(19) United States
(12) Patent Application Publication
(10) Pub. No.: US 2025/0185396 A1
(43) Pub. Date: Jun. 5, 2025

(54) IMAGE SENSOR AND ELECTRONIC APPARATUS INCLUDING THE SAME

(71) Applicant: SAMSUNG ELECTRONICS CO, LTD, Suwon-si (KR)

(72) Inventors: Sangeun MUN, Suwon-si (KR); Sookyoung ROH, Suwon-si (KR); Hyunsung Park, Suwon-si (KR); Hyeonsoo PARK, Suwon-si (KR); Hongkyu PARK, Suwon-si (KR); Sungmo AHN, Suwon-si (KR)

(73) Assignee: SAMSUNG ELECTRONICS CO, LTD., Suwon-si (KR)

(21) Appl. No.: 18/970,408

(22) Filed: Dec. 5, 2024

(30) Foreign Application Priority Data
Dec. 5, 2023 (KR) 10-2023-0174833

(51) Int. Cl. H01L 27/146; G02B 5/20; G02B 27/10

(52) U.S. Cl. CPC H10F 39/806; H10F 39/805; H10F 39/8053; G02B 5/201; G02B 27/1013

(57) ABSTRACT

Provided are an image sensor including an oblique light compensation layer, and an electronic apparatus including the image sensor. The image sensor may include a sensor substrate including a plurality of photosensing cells, each of the plurality of photosensing cells being configured to sense a light; a color separation nanostructure layer provided on the sensor substrate; a spacer layer provided on the color separation nanostructure layer; and an oblique light compensation layer provided on the spacer layer.

### CROSS-REFERENCE TO RELATED APPLICATION

This application is based on and claims priority under 35 U.S.C. § 119 to Korean Patent Application No. 10-2023-0174833, filed on Dec. 5, 2023, in the Korean Intellectual Property Office, the disclosure of which is herein incorporated by reference in its entirety.

### BACKGROUND

### 1. Field

The disclosure relates to an image sensor having improved performance at a periphery thereof by including a color separation nanostructure layer and an oblique light compensation layer, and an electronic apparatus including the image sensor.

### 2. Description of the Related Art

As image sensors and imaging modules gradually become more compact, a chief ray angle (CRA) at an edge of an image sensor tends to increase. When the chief ray angle at the edge of an image sensor increases, the sensitivity of pixels located at the edge of the image sensor decreases. Accordingly, an edge of an image may become dark. Also, an additional complex color operation for compensating for this phenomenon may impose a burden on a processor that processes an image and degrade an image processing speed.

### SUMMARY

One or more example embodiments of the disclosure provide an image sensor that may separate an incident light according to wavelengths thereof by using a color separation nanostructure layer and concentrate each separated light on a photosensing cell that senses a corresponding wavelength among photosensing cells, and an electronic apparatus including the image sensor.

Also, one or more example embodiments of the disclosure provide an image sensor including an oblique light compensation layer that may change an incidence angle of an incident light incident with a great chief ray angle at an edge of the image sensor to be close to a perpendicular angle, and an electronic apparatus including the image sensor.

Additional aspects will be set forth in part in the description which follows and, in part, will be apparent from the description, or may be learned by practice of the presented embodiments of the disclosure.

According to an aspect of the disclosure, an image sensor includes a sensor substrate including a plurality of photosensing cells, each of the plurality of photosensing cells being configured to sense a light, a color separation nanostructure layer provided on the sensor substrate and including a plurality of color separation nanostructures, each of the plurality of color separation nanostructures being configured to separate the light according to wavelengths and concentrate each separated light on a corresponding photosensing cell among the plurality of photosensing cells, a spacer layer provided on the color separation nanostructure layer, and an oblique light compensation layer provided on the spacer layer and including a plurality of oblique light compensation nanostructures,

wherein the plurality of color separation nanostructures are arranged differently for each wavelength band that is sensed by the corresponding photosensing cell and an arrangement of the plurality of color separation nanostructures provided in a peripheral portion of the color separation nanostructure layer is same as an arrangement of the plurality of color separation nanostructures provided in a central portion of the color separation nanostructure layer, and

the plurality of oblique light compensation nanostructures are configured such that a direction of an oblique light incident on the oblique light compensation layer is deflected toward the color separation nanostructure layer corresponding thereto, the plurality of oblique light compensation nanostructures are arranged differently for each position of the oblique light compensation layer, and a thickness of the spacer layer is about 1 time to about 3 times a longest wavelength among wavelengths of the light sensed by the plurality of photosensing cells.

In a central portion of the oblique light compensation layer, the plurality of oblique light compensation nanostructures may have a same width, and

in a peripheral portion of the oblique light compensation layer, in an area corresponding to each photosensing cell, a width of an oblique light compensation nanostructure closer to the central portion of the oblique light compensation layer may be greater than a width of an oblique light compensation nanostructure distant from the central portion of the oblique light compensation layer.

As a distance between an oblique light compensation nanostructure and a central portion of the oblique light compensation layer increases, a difference between a width of an oblique light compensation nanostructure closer to the central portion of the oblique light compensation layer and a width of an oblique light compensation nanostructure distant from the central portion of the oblique light compensation layer, in an area corresponding to each photosensing cell, may increase.

The plurality of oblique light compensation nanostructures may be symmetrically arranged with respect to a direction in which the light is incident on the oblique light compensation layer, in an area corresponding to each photosensing cell.

The plurality of oblique light compensation nanostructures of the oblique light compensation layer on which the light is incident in a first direction may be symmetrically arranged with respect to the first direction in the area corresponding to each photosensing cell, and the plurality of oblique light compensation nanostructures of the oblique light compensation layer on which the light is incident in a second direction may be symmetrically arranged with respect to the second direction in the area corresponding to each photosensing cell.

The image sensor may further include a color filter layer arranged between the sensor substrate and the color separation nanostructure layer and including a plurality of filters, each of which is configured to transmit only a light in a particular wavelength band and absorb or reflect light in other wavelength bands.

The image sensor may further include another spacer layer provided between the sensor substrate and the color separation nanostructure layer, wherein a thickness of the another spacer layer provided between the sensor substrate and the color separation nanostructure layer may be determined based on a focal length of the color separation nanostructure layer.

The thickness of the another spacer layer provided between the sensor substrate and the color separation nanostructure layer may be about 1.5 times to about 5 times a longest wavelength among wavelengths of a light incident on the color separation nanostructure layer.

An anti-reflection layer may be provided on the oblique light compensation layer in at least one of between the oblique light compensation layer and the spacer layer or between the spacer layer and the color separation nanostructure layer.

Each of the plurality of oblique light compensation nanostructures may include a first oblique light compensation nanostructure and a second oblique light compensation nanostructure provided on the first oblique light compensation nanostructure, the first oblique light compensation nanostructure and the second oblique light compensation nanostructure may be provided in a multi-layer structure, each of the plurality of color separation nanostructures may include a first color separation nanostructure and a second color separation nanostructure provided on the first color separation nanostructure, and the first color separation nanostructure and the second color separation nanostructure may be provided in a multi-layer structure.

Each of the plurality of oblique light compensation nanostructures may include a first oblique light compensation nanostructure and a second oblique light compensation nanostructure provided on the first oblique light compensation nanostructure, the first oblique light compensation nanostructure and the second oblique light compensation nanostructure may be provided in a multi-layer structure, and the second oblique light compensation nanostructure may be closer to a central portion of the oblique light compensation layer than the first oblique light compensation nanostructure.

At least one of the plurality of color separation nanostructures may include a first color separation nanostructure and a second color separation nanostructure provided on the first color separation nanostructure, the first color separation nanostructure and the second color separation nanostructure may be provided in a multi-layer structure, and the second color separation nanostructure may be closer to the central portion of the color separation nanostructure layer than the first color separation nanostructure.

According to another aspect of the disclosure, an electronic apparatus includes an image sensor configured to convert an optical image into an electrical signal, and a processor configured to control an operation of the image sensor and store and output a signal generated by the image sensor, wherein the image sensor includes a sensor substrate including a plurality of photosensing cells, each of the plurality of photosensing cells being configured to sense a light, a color separation nanostructure layer provided on the sensor substrate and including a plurality of color separation nanostructures, each of the plurality of color separation nanostructures being configured to separate the light according to wavelengths and concentrate each separated light on a corresponding photosensing cell among the plurality of photosensing cells, a spacer layer provided on the color separation nanostructure layer, and an oblique light compensation layer provided on the spacer layer and including a plurality of oblique light compensation nanostructures,

wherein the plurality of color separation nanostructures are arranged differently for each wavelength band sensed by the corresponding photosensing cell and an arrangement of the plurality of color separation nanostructures provided in a peripheral portion of the color separation nanostructure layer is same as an arrangement of the plurality of color separation nanostructures provided in a central portion of the color separation nanostructure layer, and

the plurality of oblique light compensation nanostructures are configured such that a direction of an oblique light incident on the oblique light compensation layer is deflected toward the color separation nanostructure layer corresponding thereto, the plurality of oblique light compensation nanostructures are arranged differently for each position of the oblique light compensation layer, and a thickness of the spacer layer is about 1 time to about 3 times a longest wavelength among the wavelengths of the light sensed by the plurality of photosensing cells.

In a central portion of the oblique light compensation layer, the plurality of oblique light compensation nanostructures may have a same width, and

in a peripheral portion of the oblique light compensation layer, in an area corresponding to each photosensing cell, a width of an oblique light compensation nanostructure closer to the central portion of the oblique light compensation layer may be greater than a width of an oblique light compensation nanostructure distant from the central portion of the oblique light compensation layer.

As a distance between an oblique light compensation nanostructure and a central portion of the oblique light compensation layer increases, a difference between a width of an oblique light compensation nanostructure closer to the central portion of the oblique light compensation layer and a width of an oblique light compensation nanostructure distant from the central portion of the oblique light compensation layer, in an area corresponding to each photosensing cell, may increase.

The plurality of oblique light compensation nanostructures may be symmetrically arranged with respect to a direction in which the light is incident on the oblique light compensation layer, in an area corresponding to each photosensing cell.

The image sensor may further include a color filter layer arranged between the sensor substrate and the color separation nanostructure layer and including a plurality of filters, each of which is configured to transmit only a light in a particular wavelength band and absorb or reflect light in other wavelength bands.

The image sensor may further include another spacer layer provided between the sensor substrate and the color separation nanostructure layer, and a thickness of the another spacer layer provided between the sensor substrate and the color separation nanostructure layer may be about 1.5 times to about 5 times a longest wavelength among wavelengths of a light incident on the color separation nanostructure layer.

### BRIEF DESCRIPTION OF THE DRAWINGS

The above and other aspects, features, and advantages of certain example embodiments of the disclosure will be more apparent from the following description taken in conjunction with the accompanying drawings, in which:

FIG. 1 is a block diagram of an image sensor according to an example embodiment;

FIGS. 2A to 2C illustrate various pixel arrangements of a pixel array of an image sensor;

FIG. 3 is a conceptual diagram schematically illustrating a camera module according to an example embodiment;

FIG. 4 is a plan view illustrating a pixel array of an image sensor according to an example embodiment;

FIG. 5 is a cross-sectional view illustrating a pixel array of an image sensor according to an example embodiment;

FIGS. 6A and 6B are schematic cross-sectional views illustrating a central portion of a pixel array of an image sensor according to an example embodiment in different cross-sections respectively, and FIGS. 6C to 6F are schematic cross-sectional views illustrating a peripheral portion of a pixel array of an image sensor according to an embodiment;

FIG. 7 is a cross-sectional view illustrating another example embodiment of the central portion of the pixel array of the image sensor of FIG. 6A;

FIG. 8 is a cross-sectional view illustrating another example embodiment of the central portion of the pixel array of the image sensor of FIG. 6A;

FIGS. 9A to 9C are cross-sectional views illustrating a central portion and a peripheral portion of a pixel array of an image sensor according to an example embodiment;

FIG. 10 is a cross-sectional view illustrating a plurality of color separation nanostructures provided in a color separation nanostructure layer of a pixel array according to an example embodiment;

FIG. 11A is a cross-sectional view illustrating an oblique light compensation nanostructure of an oblique light compensation layer in a central portion of a pixel array of an image sensor according to an example embodiment, and FIGS. 11B to 11E are cross-sectional views illustrating an oblique light compensation nanostructure of an oblique light compensation layer in a central portion of a pixel array of an image sensor according to an example embodiment;

FIGS. 12A to 12D are enlarged views illustrating a plurality of oblique light compensation nanostructures provided in an oblique light compensation layer according to example embodiments;

FIGS. 13A to 13G are diagrams conceptually illustrating a pixel array constituting a unit pixel array;

FIG. 14 is a block diagram schematically illustrating an electronic apparatus including an image sensor according to example embodiments;

FIG. 15 is a block diagram schematically illustrating a camera module illustrated in FIG. 14;

FIG. 16 is a block diagram of an electronic apparatus including a multi-camera module according to an example embodiment; and

FIG. 17 is a detailed block diagram of a camera module of the electronic apparatus illustrated in FIG. 16.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, an image sensor and an electronic apparatus including the same will be described in detail with reference to accompanying drawings. The described embodiments are merely examples, and various modifications may be made therein. Like reference numerals in the drawings will denote like elements, and sizes of elements in the drawings may be exaggerated for clarity and convenience of description.

When an element is referred to as being “on” or “over” another element, it may be directly or indirectly on or over/under/at left/right sides of the other element.

Although terms such as “first” and “second” may be used herein to describe various elements, these terms are only used to distinguish an element from another element. These terms are not intended to limit that the materials or structures of elements are different from each other.

As used herein, the singular forms “a”, “an”, and “the” are intended to include the plural forms as well, unless the context clearly indicates otherwise. Also, when something is referred to as “including” a component, another component may be further included unless specified otherwise.

Also, as used herein, the terms “units” and “modules” may refer to units that perform functions or operations, and the units may be implemented as hardware or software or a combination of hardware and software.

The use of the terms “a”, “an”, and “the” and other similar indicative terms may be construed to cover both the singular and the plural.

Operations of a method described herein may be performed in any suitable order unless otherwise specified. Also, example terms (e.g., “such as” and “and/or the like”) used herein are merely intended to describe the technical concept of the disclosure in detail, and the scope of the disclosure is not limited by the example terms unless otherwise defined in the appended claims.

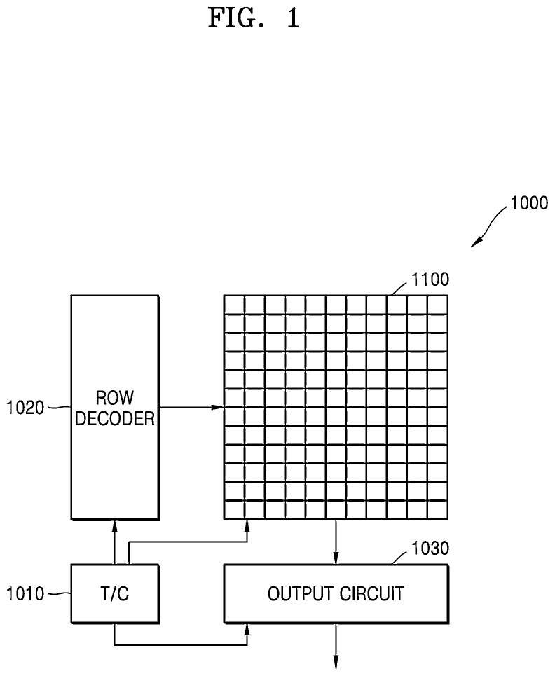

FIG. 1 is a block diagram of an image sensor according to an example embodiment. Referring to FIG. 1, an image sensor 1000 may include a pixel array 1100, a timing controller 1010, a row decoder 1020, and an output circuit 1030. The image sensor 1000 may be, for example, a charge coupled device (CCD) image sensor or a complementary metal oxide semiconductor (CMOS) image sensor.

The pixel array 1100 may include pixels that are two-dimensionally arranged in a plurality of rows and a plurality of columns. The row decoder 1020 may select one of the plurality of rows of the pixel array 1100 in response to a row address signal output from the timing controller 1010. The output circuit 1030 may output a light sensing signal in a column unit from a plurality of pixels arranged in the selected row. For this purpose, the output circuit 1030 may include a column decoder and an analog-to-digital converter (ADC). For example, the output circuit 1030 may include a plurality of ADCs arranged respectively for the plurality of columns between the column decoder and the pixel array 1100, or one ADC arranged at an output terminal of the column decoder. The timing controller 1010, the row decoder 1020, and the output circuit 1030 may be implemented as one chip or as separate chips. A processor for processing an image signal output from the output circuit 1030 may be implemented as one chip with the timing controller 1010, the row decoder 1020, and the output circuit 1030.

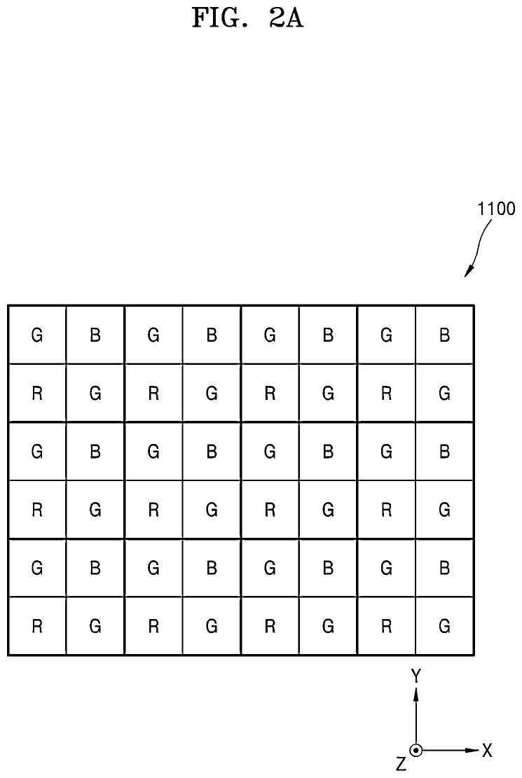

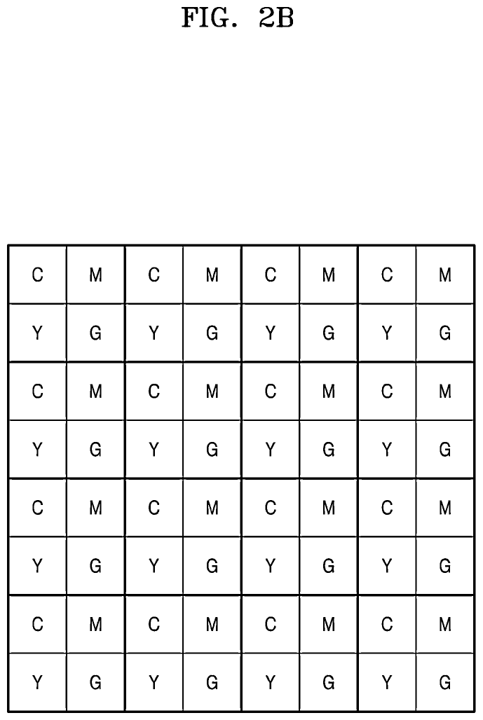

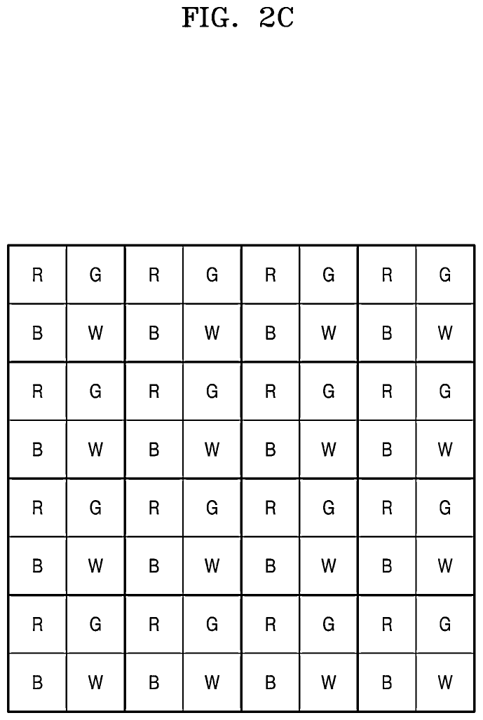

The pixel array 1100 may include a plurality of pixels that sense light of different wavelengths. The arrangement of the plurality of pixels may be implemented in various ways. For example, FIGS. 2A to 2C illustrate various pixel arrangements of a pixel array of an image sensor according to an example embodiment.

FIG. 2A illustrates a Bayer pattern that may be adopted in a general image sensor. Referring to FIG. 2A, one unit pattern may include four quadrant regions, and first to fourth quadrants may include a green pixel G, a blue pixel B, a red pixel R, and a green pixel G. The unit patterns may be repeatedly and two-dimensionally arranged in a first direction (e.g., X direction) and a second direction (e.g., Y direction). In other words, two green pixels G may be arranged in one diagonal direction and one blue pixel B and one red pixel R may be arranged in another diagonal direction in a unit pattern of a 2×2 array. In an entire pixel arrangement of the pixel array 1100, a first row in which a plurality of green pixels G and a plurality of blue pixels B are alternately arranged in the first direction and a second row in which a plurality of red pixels R and a plurality of green pixels G are alternately arranged in the first direction may be repeatedly arranged in the second direction.

The pixels of the pixel array 1100 may also be arranged in various arrangement patterns other than the Bayer pattern. For example, referring to FIG. 2B, a CYGM arrangement, in which a magenta pixel M, a cyan pixel C, a yellow pixel Y, and a green pixel G constitute one unit pattern, may be used. Also, referring to FIG. 2C, an RGBW arrangement, in which a green pixel G, a red pixel R, a blue pixel B, and a white pixel W constitute one unit pattern, may be used. Also, although not illustrated, the unit pattern may have a 3×2 array form. In addition, the pixels of the pixel array 1100 may be arranged in various ways according to a purpose and a characteristic of the image sensor 1000. Hereinafter, it will be described as an example that the pixel array 1100 of the image sensor 1000 has a Bayer pattern; however, the operation principles may also be applied to any other patterns of pixel arrangement than the Bayer pattern.

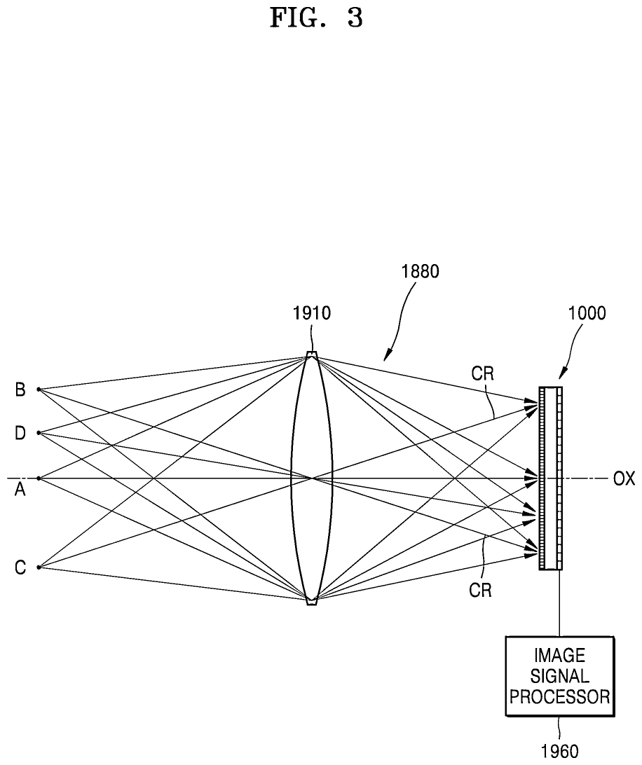

The image sensor 1000 may be applied to various optical apparatuses such as camera modules. For example, FIG. 3 is a conceptual diagram schematically illustrating a camera module according to an example embodiment.

Referring to FIG. 3, a camera module 1880 according to an example embodiment may include a lens assembly 1910 configured to form an optical image by focusing the light reflected from an object, an image sensor 1000 configured to convert the optical image formed by the lens assembly 1910 into an electrical image signal, and an image signal processor 1960 configured to process the electrical signal output from the image sensor 1000 into an image signal. Also, the camera module 1880 may further include an infrared blocking filter (not shown) arranged between the image sensor 1000 and the lens assembly 1910, a display panel (not shown) configured to display an image formed by the image signal processor 1960, and a memory (not shown) configured to store image data formed by the image signal processor 1960. The camera module 1880 may be mounted, for example, on a mobile electronic apparatus such as a mobile phone, a notebook computer, or a tablet PC.

The lens assembly 1910 may focus an image of an object outside the camera module 1880 onto the image sensor 1000, more particularly, onto the pixel array 1100 of the image sensor 1000. For convenience, in FIG. 3, the lens assembly 1910 is briefly illustrated as being a single lens; however, the lens assembly 1910 may include a plurality of lenses. When the pixel array 1100 is accurately located on a focal plane of the lens assembly 1910, a light starting from a point on the object may be re-collected at a point on the pixel array 1100 through the lens assembly 1910. For example, a light starting from a point A on an optical axis OX may be collected at a center of the pixel array 1100 on the optical axis OX after passing through the lens assembly 1910. The light starting from a point B, C, or D off the optical axis OX may be collected by the lens assembly 1910 at a point on a peripheral portion of the pixel array 1100 across the optical axis OX. For example, in FIG. 3, a light starting from the point B above the optical axis OX may be collected at a lower edge of the pixel array 1100 across the optical axis OX, and a light starting from the point C below the optical axis OX may be collected at an upper edge of the pixel array 1100 across the optical axis OX. Also, a light starting from the point D located between the optical axis OX and the point B may be collected between the center and the lower edge of the pixel array 1100.

Thus, the lights respectively starting from different points A, B, C, and D may be incident on the pixel array 1100 at different angles depending on distances between the points A, B, C, and D and the optical axis OX. The incidence angle of light incident on the pixel array 1100 may be generally defined as a chief ray angle (CRA). A chief ray may refer to a ray that is incident from one point of the object through a center of the lens assembly 1910 onto the pixel array 1100, and the chief ray angle may refer to an angle between the chief ray and the optical axis OX. The light starting from the point A on the optical axis OX may have a chief ray angle of 0 degree and may be perpendicularly incident on the pixel array 1100. As a distance of a starting point of a light from the optical axis OX increases, the chief ray angle thereof may increase.

From a viewpoint of the image sensor 1000, the chief ray angle of a light incident on a central portion of the pixel array 1100 may be 0 degree, and the chief ray angle of the incident light may increase toward the edge of the image sensor 1100. For example, the chief ray angle of the light starting from the point B and the light starting from the point C and incident on the edge of the pixel array 1100 may be greatest, and the chief ray angle of the light starting from the point A and incident on the central portion of the pixel array 1100 may be 0 degree. Also, the chief ray angle of the light starting from the point D and incident between the center and the edge of the pixel array 1100 may be less than the chief ray angle of the light starting from the point B or the point C and greater than 0 degree.

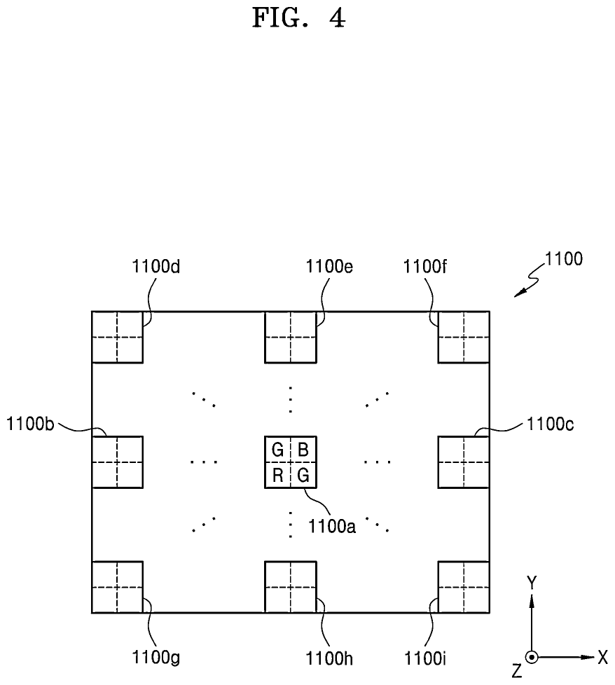

Thus, the chief ray angle of the incident light incident on a pixel may vary depending on a position of the pixel in the pixel array 1100. For example, FIG. 4 is a plan view illustrating a pixel array of an image sensor according to an example embodiment.

Referring to FIG. 4, in a central portion 1100a of the pixel array 1100, the chief ray angle may be 0 degree in both the first direction (e.g., X direction) and the second direction (e.g., Y direction). Also, the chief ray angle in the first direction may gradually increase as the distance from the central portion 1100a in the first direction increases, and the chief ray angle in the first direction may be greatest at both edges 1100b and 1100c in the first direction. Also, the chief ray angle in the second direction may gradually increase as the distance from the central portion 1100a in the second direction increases, and the chief ray angle in the second direction may be greatest at both edges 1100e and 1100h in the second direction. Also, both the chief ray angle in the first direction and the chief ray angle in the second direction may gradually increase as the distance from the central portion 1100a in the diagonal direction increases, and the chief ray angle in the first and second directions (or in the diagonal direction) may be greatest at vertexes 1100d, 1100f, 1100g, and 1100i. When the chief ray angle of the incident light incident on the pixels increases, the sensitivity of the pixels may decrease. According to an embodiment, in order to prevent or minimize a decrease in the sensitivity of pixels located at the edge of the pixel array 1100, an oblique light compensation layer and a color separation nanostructure layer may be arranged in the pixel array 1100 of the image sensor 1000.

Throughout the disclosure, the central portion 1100a of the pixel array 1100 may also be referred to as a central portion of the color separation nanostructure layer or the oblique light compensation layer. Throughout the disclosure, the peripheral portion of the pixel array 1100 may also be referred to as a peripheral portion of the color separation nanostructure layer or the oblique light compensation layer.

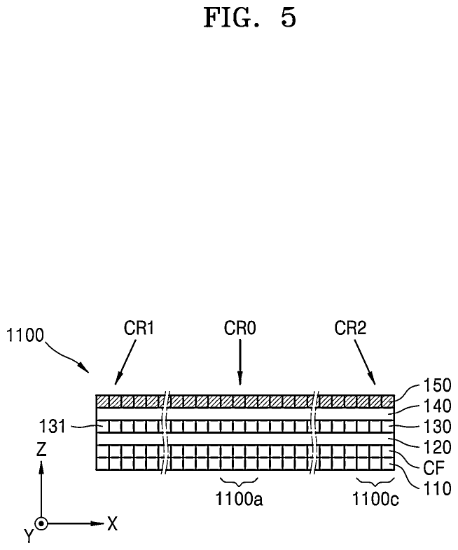

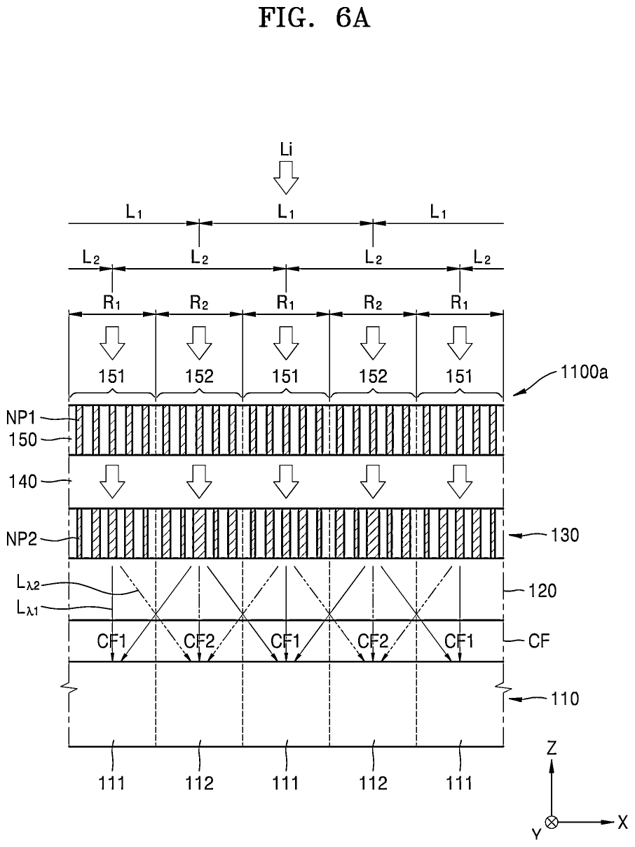

FIG. 5 is a cross-sectional view illustrating a pixel array of an image sensor according to an example embodiment.

Referring to FIG. 5, a pixel array 1100 of the image sensor 1000 may include a sensor substrate 110, a color filter layer CF provided on or over the sensor substrate 110, a first spacer layer 120 provided on or over the color filter layer CF, a color separation nanostructure layer 130 provided on or over the first spacer layer 120, a second spacer layer 140 provided on or over the color separation nanostructure layer 130, and an oblique light compensation layer 150 provided on or over the second spacer layer 140. As illustrated in FIG. 5, a chief ray CR0 incident on a central portion 1100a of the pixel array 1100 may be incident on the pixel array 1100 at an angle perpendicular to or substantially perpendicular to the pixel array 1100, whereas chief rays CR1 and CR2 incident on a peripheral portion (e.g., 1100c) of the pixel array 1100 may be obliquely incident on the pixel array 1100. Thus, the oblique light compensation layer 150 in the central portion 1100a of the pixel array 1100 and the oblique light compensation layer 150 in the peripheral portion (e.g., 1100c) of the pixel array 1100 may be designed differently by considering incidence angles of the chief rays CR0, CR1, and CR2.

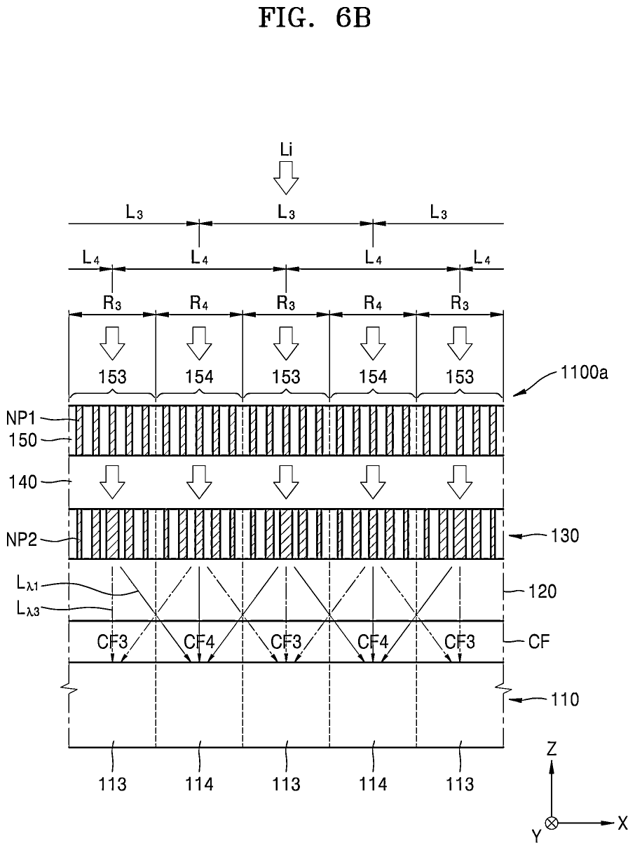

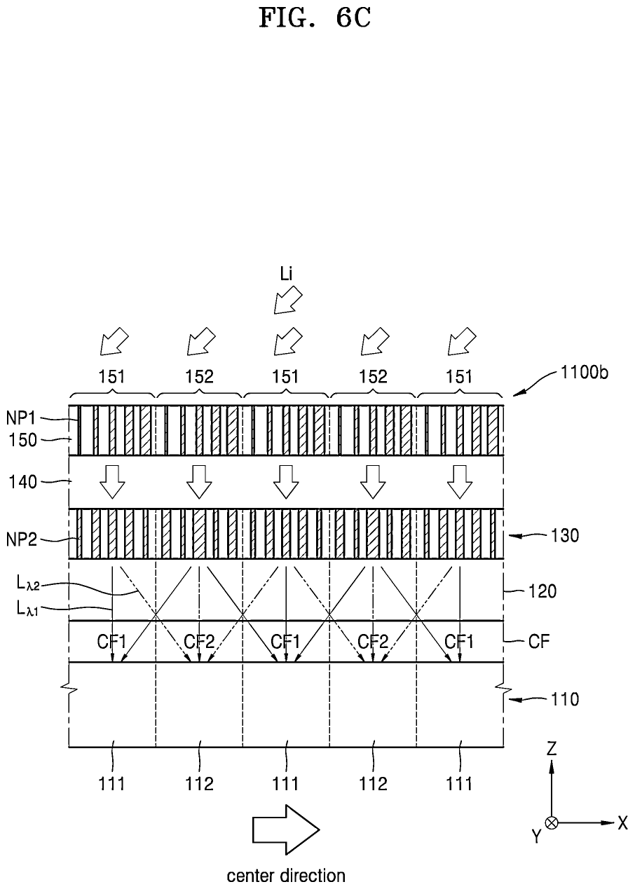

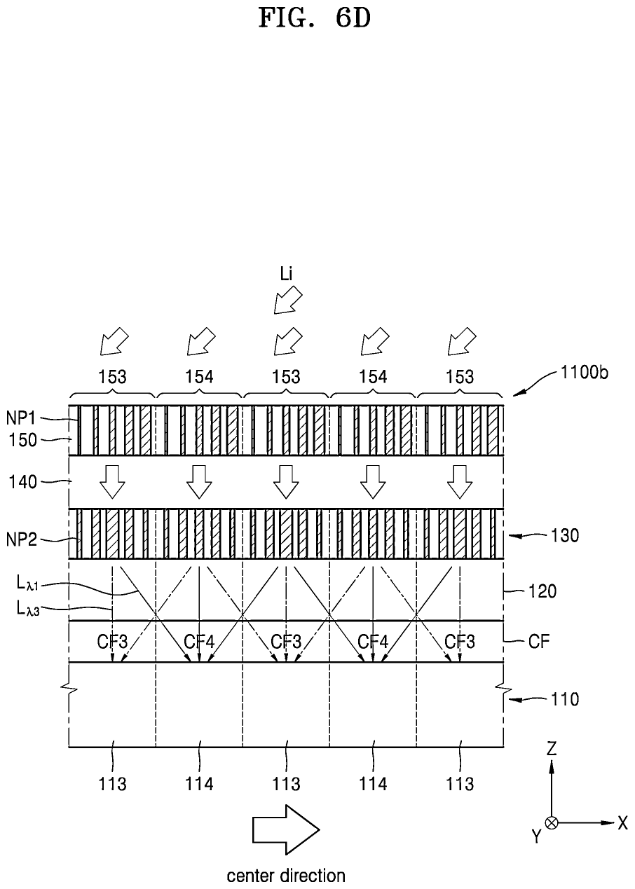

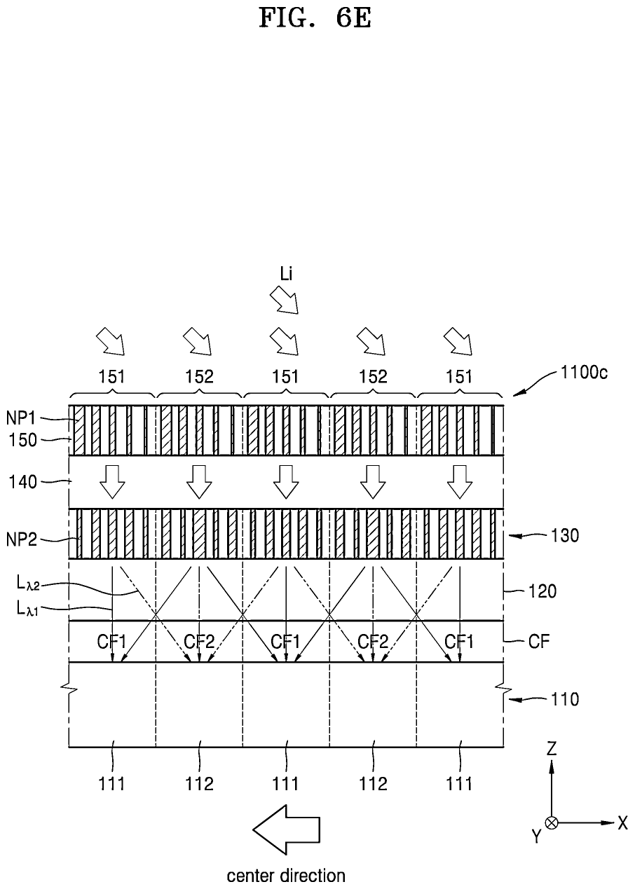

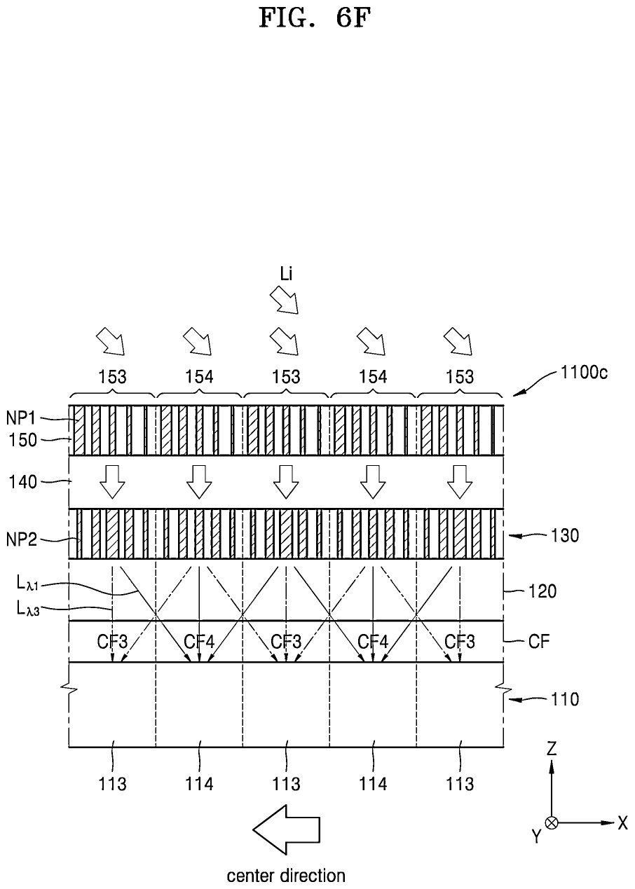

FIGS. 6A and 6B are schematic cross-sectional views illustrating a central portion of a pixel array of an image sensor according to an example embodiment in different cross-sections respectively.

Referring to FIGS. 6A and 6B, a pixel array 1100 of the image sensor 1000 may include a sensor substrate 110 including a plurality of photosensing cells (or pixels) 111, 112, 113, and 114, a color filter layer CF provided on or over the sensor substrate 110, a first spacer layer 120 provided on or over the color filter layer CF, a color separation nanostructure layer 130 provided on or over the first spacer layer 120, a second spacer layer 140 provided on or over the color separation nanostructure layer 130, and an oblique light compensation layer 150 provided on or over the second spacer layer 140.

The sensor substrate 110 may include a plurality of photosensing cells 111, 112, 113, and 114 that sense light. For example, the sensor substrate 110 may include a first photosensing cell 111, a second photosensing cell 112, a third photosensing cell 113, and a fourth photosensing cell 114 that convert light into an electrical signal. As illustrated in FIG. 6A, the first photosensing cell 111 and the second photosensing cell 112 may be alternately arranged in the first direction (e.g., X direction), and as illustrated in FIG. 6B, the third photosensing cell 113 and the fourth photosensing cell 114 may be alternately arranged in the first direction (e.g., X direction) in cross-sections at different positions. This arrangement may be used for sensing an incident light by dividing the incident light based on unit patterns such as Bayer patterns, and a plurality of unit patterns including the first to fourth photosensing cells 111, 112, 113, and 114 may be two-dimensionally arranged in the first direction and the second direction. For example, the first and fourth photosensing cells 111 and 114 may sense a green light, the second photosensing cell 112 may sense a blue light, and the third photosensing cell 113 may sense a red light. Although not illustrated, a separation layer for cell separation may be further provided at an inter-cell boundary (e.g., a boundary between cells).

The color filter layer CF may be provided on or over the sensor substrate 110. The color filter layer CF may include a plurality of color filters CF1, CF2, CF3, and CF4 that each transmit only a light in a particular wavelength band and absorb or reflect a light in other wavelength bands. For example, the color filter layer CF may include a first color filter CF1 provided on or over the first photosensing cell 111 to transmit only a light in a first wavelength band, a second color filter CF2 provided on or over the second photosensing cell 112 to transmit only a light in a second wavelength band different from the first wavelength band, a third color filter CF3 provided on or over the third photosensing cell 113 to transmit only a light in a third wavelength band different from the first and second wavelength bands, and a fourth color filter CF4 provided on or over the fourth photosensing cell 114 to transmit only a light in the first wavelength band. Thus, the first color filter CF1 and the second color filter CF2 may be alternately arranged in the first direction, and the third color filter CF3 and the fourth color filter CF4 may be alternately arranged at different positions in the second direction, in a cross-section cut along a different line. For example, the first and fourth color filters CF3 and CF4 may transmit only a green light, the second color filter CF2 may transmit only a blue light, and the third color filter CF3 may transmit only a red light. The first to fourth color filters CF1 to CF4 may be two-dimensionally arranged in the first and second directions. The first to fourth color filters CF1 to CF4 may include an organic material.

The first spacer layer 120 may be provided on or over the color filter layer CF. A thickness of the first spacer layer 120 may be determined by considering a focal length of the color separation nanostructure layer 130 described below. The first spacer layer 120 may provide a sufficient light propagation distance for modulating a phase profile. For example, the thickness of the first spacer layer 120 may be about 1.5 times to about 5 times a longest wavelength among wavelengths incident on the color separation nanostructure layer 130. The thickness of the first spacer layer 120 may be about 900 nm to about 3,000 nm. As another example, the thickness of the first spacer layer 120 may be less than the focal length of the wavelength incident on the color separation nanostructure layer 130. A focus of a light that has passed through the color separation nanostructure layer 130 may be located at a color filter or a photosensing cell.

The first spacer layer 120 may include a planarization layer (not shown) and an encapsulation layer (not shown). The encapsulation layer may be provided between the color filter layer CF and the color separation nanostructure layer 130 described below, to prevent a contamination between the first to fourth color filters CF1 to CF4 and a color separation nanostructure NP2 of the color separation nanostructure layer 130 including an inorganic material when the color filter layer CF includes an organic material. The planarization layer may be provided to eliminate and planarize different steps between colors of the color filter layer CF. A bottom level of the planarization layer may be different for each color of the color filter layer CF, and a top level of the planarization layer may be uniform among colors of the color filter layer CF.

The color separation nanostructure layer 130 may be partitioned in various ways. For example, the color separation nanostructure layer 130 may be partitioned into first to fourth pixel corresponding areas R₁, R₂, R₃, and R₄ respectively corresponding to the first to fourth photosensing cells 111, 112, 113, and 114. The first pixel corresponding area R₁ and the second pixel corresponding area R₂ may respectively face the first photosensing cell 111 on which a first-wavelength light L_{λ}_{₁} included in an incident light Li is concentrated and the second photosensing cell 112 on which a second-wavelength light L_{λ}_{₂} included in the incident light Li is concentrated. The third pixel corresponding area R₃ and the fourth pixel corresponding area R₄ may respectively face the third photosensing cell 113 on which a third-wavelength light L_{λ}_{₃} included in the incident light Li is concentrated and the fourth photosensing cell 114 on which the first-wavelength light L_{λ}_{₁} included in the incident light Li is concentrated. The first to fourth pixel corresponding areas R₁, R₂, R₃, and R₄ may be two-dimensionally arranged in the first direction (e.g., X direction) and the second direction (e.g., Y direction) such that a first row in which the first pixel corresponding area R₁ and the second pixel corresponding area R₂ are alternately arranged and a second row in which the third pixel corresponding area R₃ and the fourth pixel corresponding area R₄ are alternately arranged may be alternately repeated. As another example, the color separation nanostructure layer 130 may be partitioned into a first wavelength concentration area Li for concentrating the first-wavelength light L_{λ}_{₁} on the first photosensing cell 111, a second wavelength concentration area L₂ for concentrating the second-wavelength light L_{λ}_{₂} on the second photosensing cell 112, a third wavelength concentration area Ls for concentrating the third-wavelength light L_{λ}_{₃} on the third photosensing cell 113, and a fourth wavelength concentration area L₄ for concentrating the first-wavelength light L_{λ}_{₁} on the fourth photosensing cell 114. The areas of the first to fourth wavelength concentration areas L₁, L₂, L₃, and L₄ may be respectively greater than the areas of the first to fourth photosensing cells 111, 112, 113, and 114 corresponding thereto. The first wavelength light concentration area L₁ to the fourth wavelength light concentration area L₄ may partially overlap each other. Each of the first to fourth pixel corresponding areas R₁, R₂, R₃, and R₄ may include a plurality of color separation nanostructures NP2.

The color separation nanostructure layer 130 may be configured to form different phase profiles for the first-wavelength light L_{λ}_{₁} the second-wavelength light L_{λ}_{₂}, and the third-wavelength light L_{λ}_{₃} included in the incident light Li to concentrate the first-wavelength light L_{λ}_{₁} on the first photosensing cell 111 and the fourth photosensing cell 114, concentrate the second-wavelength light L_{λ}_{₂} on the second photosensing cell 112, and concentrate the third-wavelength light L_{λ}_{₃} on the third photosensing cell 113.

The color separation nanostructure layer 130 may include a plurality of color separation nanostructures NP2 for changing the phase of the incident light Li differently depending on the incident positions thereof. The plurality of color separation nanostructures NP2 of the color separation nanostructure layer 130 may be configured to form different phase profiles for the first to third-wavelength lights included in the incident light L₁ to achieve the color separation between the pixels. Because a refractive index of a material varies depending on a wavelength of an incident light, the color separation nanostructure layer 130 may provide different phase profiles for the first to third-wavelength lights L_{λ}_{₁}, L_{λ}_{₂}, and L_{λ}_{₃}. In other words, because the same material has a different refractive index according to a wavelength of a light reacting with the material and a phase delay of a light having passed through the material is different according to a wavelength of the light, the phase profile may vary depending on the wavelength of the light. For example, because a refractive index of the first pixel corresponding area R₁ with respect to the first-wavelength light L_{λ}_{₁} and a refractive index of the first pixel corresponding area R₁ with respect to the second-wavelength light L_{λ}_{₂} may be different from each other and a phase delay of the first-wavelength light L_{λ}_{₁} having passed through the first pixel corresponding area R₁ and a phase delay of the second-wavelength light L), having passed through the first pixel corresponding area R₁ may be different from each other, when the color separation nanostructure layer 130 is designed based on these characteristics of light, different phase profiles may be provided for the first to third-wavelength lights L_{λ}_{₁}, L_{λ}_{₂}, and L_{λ}_{₃}. Each of the first to fourth pixel corresponding areas R₁, R₂, R₃, and R₄ may include a plurality of color separation nanostructures NP2 capable of separating colors of light and concentrating light. The shape, size (e.g., width and height), interval, arrangement form, or the like of the plurality of color separation nanostructures NP2 may be determined to have a certain phase profile according to a wavelength of a light immediately after having passed through each of the first to fourth pixel corresponding areas R₁, R₂, R₃, and R₄. According to this phase profile, the propagation direction and focal length of the light having passed through each of the first to fourth pixel corresponding areas R₁, R₂, R₃, and R₄ may be determined.

The color separation nanostructure NP2 may include a nanopillar of which a cross-sectional diameter (or width) has a sub-wavelength dimension. Here, the sub-wavelength may refer to a wavelength that is less than a wavelength band of light to be concentrated. When the incident light is visible light, the cross-sectional diameter of the color separation nanostructure NP2 may be less than, for example, 400 nm, 300 nm, or 200 nm. Moreover, a height of the color separation nanostructure NP2 may be about 500 nm to about 1,500 nm and may be greater than the cross-sectional diameter thereof.

The color separation nanostructure NP2 may include a material that has a relatively high refractive index compared to a peripheral material (or a material that is at a periphery of the color separation nanostructure NP2) and has a relatively low absorption factor in the visible light band. For example, the color separation nanostructure NP2 may include c-Si, p-Si, a-Si, a Group III-V compound semiconductor (GaP, GaN, GaAs, or the like), SiC, TiO₂, SiN₃, ZnS, ZnSe, Si₃N₄, or any combination thereof. The periphery of the color separation nanostructure NP2 may be filled with a dielectric material that has a relatively lower refractive index than the color separation nanostructure NP2 and has a relatively low absorption factor in the visible light band. For example, the periphery of the color separation nanostructure NP2 may be filled with SiO₂, siloxane-based spin-on-glass (SOG), air, or the like. The color separation nanostructure NP2 having a refractive index difference from the peripheral material may change the phase of a light passing through the color separation nanostructure NP2. This may be caused by a phase delay that occurs due to a shape dimension of the sub-wavelength of the color separation nanostructure NP2, and a degree at which the phase is delayed may be determined by a detailed shape dimension and/or arrangement form of the color separation nanostructure NP2.

The width and arrangement of the plurality of color separation nanostructures NP2 provided in each of the first to fourth pixel corresponding areas R₁, R₂, R₃, and R₄ may be different for each wavelength band sensed by the photosensing cell corresponding to each pixel corresponding area. For example, the width and arrangement of the plurality of color separation nanostructures NP2 provided in the first pixel corresponding area R₁ may be different from the width and arrangement of the plurality of color separation nanostructures NP2 provided in each of the second to fourth pixel corresponding areas R₂, R₃, and R₄. For convenience, the first pixel corresponding area R₁ has been described above as an example, and the above description may also be similarly applied to the second to fourth pixel corresponding areas R₂, R₃, and R₄.

Also, the width and arrangement of the plurality of color separation nanostructures NP2 provided in each of the first to fourth pixel corresponding areas R₁, R₂, R₃, and R₄ may be the same in the same pixel corresponding area in the central portion 1100a and peripheral portions 1100b to 1100i of the pixel array 1100. That is, the width and arrangement of the plurality of color separation nanostructures NP2 provided in the first pixel corresponding area R₁ in the central portion 1100a of the pixel array 1100 may be the same as the width and arrangement of the plurality of color separation nanostructures NP2 provided in the first pixel corresponding area R₁ in the peripheral portions 1100b to 1100i of the pixel array 1100. For convenience, the first pixel corresponding area R₁ has been described above as an example, and the above description may also be similarly applied to the second to fourth pixel corresponding areas R₂, R₃, and R₄.

The second spacer layer 140 may be provided on or over the color separation nanostructure layer 130. The second spacer layer 140 may prevent a mutual interference between the color separation nanostructure layer 130 and the oblique light compensation layer 150 arranged with the second spacer layer 140 therebetween. Also, the second spacer layer 140 may provide a sufficient light propagation distance for modulating the phase profile deflecting the incident light. For this purpose, a thickness of the second spacer layer 140 may be sufficiently great. For example, the thickness of the second spacer layer 140 may be about 1 time to about 3 times the longest wavelength among the wavelengths transmitted by the plurality of photosensing cells 111, 112, 113, and 114. For example, the thickness of the second spacer layer 140 may be about 600 nm to about 1,800 nm.

The oblique light compensation layer 150 may be provided on or over the second spacer layer 140. The oblique light compensation layer 150 may include a plurality of oblique light compensation nanostructures NP1. The oblique light compensation nanostructure NP1 may include a nanopillar of which a cross-sectional diameter (or width) has a sub-wavelength dimension. When the incident light is visible light, the cross-sectional diameter of the oblique light compensation nanostructure NP1 may be less than, for example, 400 nm, 300 nm, or 200 nm. Moreover, a height of the oblique light compensation nanostructure NP1 may be about 500 nm to about 1,500 nm and may be greater than the cross-sectional diameter thereof.

The oblique light compensation nanostructure NP1 may include a material that has a relatively high refractive index compared to a peripheral material and has a relatively low absorption factor in the visible light band. For example, the oblique light compensation nanostructure NP1 may include c-Si, p-Si, a-Si, a Group III-V compound semiconductor (GaP, GaN, GaAs, or the like), SiC, TiO₂, SiN₃, ZnS, ZnSe, Si₃N₄, or any combination thereof. A periphery of the oblique light compensation nanostructure NP1 may be filled with a dielectric material that has a relatively lower refractive index than the oblique light compensation nanostructure NP1 and has a relatively low absorption factor in the visible light band. For example, the periphery of the oblique light compensation nanostructure NP1 may be filled with SiO₂, siloxane-based spin-on-glass, air, or the like. The oblique light compensation nanostructure NP1 having a refractive index difference from the peripheral material may change the propagation direction of the incident light passing through the oblique light compensation nanostructure NP1.

The oblique light compensation nanostructure NP1 of the oblique light compensation layer 150 may be arranged to compensate an oblique light of the light incident on the oblique light compensation layer 150. The size and/or arrangement of the oblique light compensation nanostructure NP1 of the oblique light compensation layer 150 may be different depending on a position of a corresponding photosensing cell to compensate an oblique light of the light incident on the oblique light compensation layer 150.

The oblique light compensation layer 150 may be divided into a plurality of oblique light compensation areas 151, 152, 153, and 154 according to the photosensing cells 111, 112, 113, and 114 respectively corresponding thereto. The plurality of oblique light compensation areas 151, 152, 153, and 154 may respectively correspond to the photosensing cells 111, 112, 113, and 114 on a one-to-one basis.

For example, a first oblique light compensation area 151 provided on or over the first photosensing cell 111 may correspond to the first photosensing cell 111, and a second oblique light compensation area 152 provided on or over the second photosensing cell 112 may correspond to the second photosensing cell 112. Also, a third oblique light compensation area 153 provided on or over the third photosensing cell 113 may correspond to the third photosensing cell 113, and a fourth oblique light compensation area 154 provided on or over the fourth photosensing cell 114 may correspond to the fourth photosensing cell 114. The first oblique light compensation area 151 and the second oblique light compensation area 152 may be alternately arranged in the first direction, and the third oblique light compensation area 153 and the fourth oblique light compensation area 154 may be alternately arranged in the second direction in cross-sections at different positions.

The first to fourth oblique light compensation areas 151, 152, 153, and 154 may be two-dimensionally arranged in the first and second directions to face the corresponding photosensing cells. For example, the first photosensing cell 111 and the first oblique light compensation area 151 may be arranged to face each other in a third direction (e.g., Z direction) perpendicular to the first and second directions. Also, the second photosensing cell 112 and the second oblique light compensation area 152 may be arranged to face each other in the third direction, the third photosensing cell 113 and the third oblique light compensation area 153 may be arranged to face each other in the third direction, and the fourth photosensing cell 114 and the fourth oblique light compensation area 154 may be arranged to face each other in the third direction.

The first oblique light compensation area 151 may correspond to the first pixel corresponding area R₁, the second oblique light compensation area 152 may correspond to the second pixel corresponding area R₂, the third oblique light compensation area 153 may correspond to the third pixel corresponding area R₃, and the fourth oblique light compensation area 154 may correspond to the fourth pixel corresponding area R₄. The oblique light compensation nanostructure NP1 of the oblique light compensation layer 150 may be configured such that the direction of oblique light incident on the oblique light compensation layer 150 is deflected toward the color separation nanostructure layer 130 corresponding thereto.

The width and/or arrangement of a plurality of oblique light compensation nanostructures NP1 provided in each of the first to fourth oblique light compensation areas 151, 152, 153, and 154 may be different in the central portion 1100a and the peripheral portion of the pixel array 1100. That is, the width and/or arrangement of the plurality of oblique light compensation nanostructures NP1 provided in the first oblique light compensation area 151 in the central portion 1100a of the pixel array 1100 may be different from the width and/or arrangement of the plurality of oblique light compensation nanostructures NP1 provided in the first oblique light compensation area 151 in the peripheral portion of the pixel array 1100. For convenience, the first oblique light compensation area 151 has been described above as an example, and the above description may also be similarly applied to the second to fourth oblique light compensation areas 152, 153, and 154. In the case of the central portion 1100a of the pixel array 1100, because an incident light is perpendicularly incident thereon, it may not be necessary to correct an oblique light and the widths of the plurality of oblique light compensation nanostructures NP1 of the oblique light compensation layer 150 in the central portion 1100a of the pixel array 1100 may be the same as each other regardless of positions thereof.

Also, in the oblique light compensation areas 151, 152, 153, and 154 in the central portion 1100a of the pixel array 1100, the plurality of oblique light compensation nanostructures NP1 may be arranged to have a symmetrical structure. For example, the plurality of oblique light compensation nanostructures NP1 provided in the oblique light compensation areas 151, 152, 153, and 154 in the central portion 1100a of the pixel array 1100 may be arranged in a form of 4-fold symmetry.

On the other hand, in the case of the peripheral portion of the pixel array 1100, because an incident light is incident thereon at angles other than the perpendicular angle, it may be necessary to correct an oblique light and the width and/or arrangement of the plurality of oblique light compensation nanostructures NP1 provided in the oblique light compensation layer 150 in the peripheral portion of the pixel array 1100 may be different from the width and/or arrangement of the plurality of oblique light compensation nanostructures NP1 provided in the oblique light compensation layer 150 in the central portion 1100a of the pixel array 1100. For example, the width and/or arrangement of the plurality of oblique light compensation nanostructures NP1 provided in the oblique light compensation layer 150 in the peripheral portion of the pixel array 1100 may be different for each position thereof. Also, in the oblique light compensation areas 151, 152, 153, and 154 in the peripheral portion of the pixel array 1100, an area with a symmetrical structure and an area without a symmetrical structure may coexist in the plurality of oblique light compensation nanostructures NP1. For example, the plurality of oblique light compensation nanostructures NP1 may be arranged in a form of 2-fold symmetry in the oblique light compensation areas 151, 152, 153, and 154 of first-direction edges 1100b and 1100c, second-direction edges 1100e and 1100h, and diagonal-direction edges 1100d, 1100f, 1100g, and 1100i of the pixel array 1100, and the plurality of oblique light compensation nanostructures NP1 may not have a symmetrical structure in the other oblique light compensation areas 151, 152, 153, and 154 of the peripheral portion of the pixel array 1100.

FIGS. 6C to 6D are schematic cross-sectional views illustrating a first-direction one-side edge 1100b of a pixel array 1100 of an image sensor according to an embodiment in different cross-sections respectively. On the one-side edge 1100b of the pixel array 1100 in the first direction (e.g., plus (+) X direction), an incident light Li may be incident in a direction opposite to the first direction (e.g., direction away from the first direction or direction tilted away from the first direction). The oblique light compensation nanostructures NP1 of the oblique light compensation layer 150 may be configured to compensate for a phase difference due to oblique light of the incident light Li incident in the direction opposite to the first direction. The oblique light compensation nanostructures NP1 of the oblique light compensation layer 150 may be configured such that the direction of oblique light incident on the oblique light compensation layer 150 is deflected toward the color separation nanostructure layer 130 corresponding thereto. For example, the oblique light compensation layer 150 provided in the one-side edge 1100b in the first direction may be configured such that the oblique light compensation nanostructures NP1 are arranged with greater widths toward the center direction of the pixel array 1100 in each of the oblique light compensation areas 151, 152, 153, and 154. The incident light Li obliquely incident on the oblique light compensation layer 150 may be perpendicularly incident on the second spacer layer 140 by passing through the oblique light compensation layer 150.

FIGS. 6E to 6F are schematic cross-sectional views illustrating a first-direction other-side edge 1100c of a pixel array 1100 of an image sensor according to an example embodiment in different cross-sections respectively. On the other-side edge 1100c of the pixel array 1100 in the first direction (e.g., plus (+) X direction), an incident light Li may be incident toward the first direction (or tilted toward the first direction). The oblique light compensation nanostructures NP1 of the oblique light compensation layer 150 may be configured to compensate for a phase difference due to oblique light of the incident light Li incident in the first direction. The oblique light compensation nanostructures NP1 of the oblique light compensation layer 150 may be configured such that the direction of oblique light incident on the oblique light compensation layer 150 is deflected toward the color separation nanostructure layer 130 corresponding thereto. For example, the oblique light compensation layer 150 provided in the other-side edge 1100c in the first direction may be configured such that the oblique light compensation nanostructures NP1 are arranged with greater widths toward the center direction of the pixel array 1100 in each of the oblique light compensation areas 151, 152, 153, and 154. The incident light Li obliquely incident on the oblique light compensation layer 150 may be perpendicularly incident on the second spacer layer 140 by passing through the oblique light compensation layer 150.

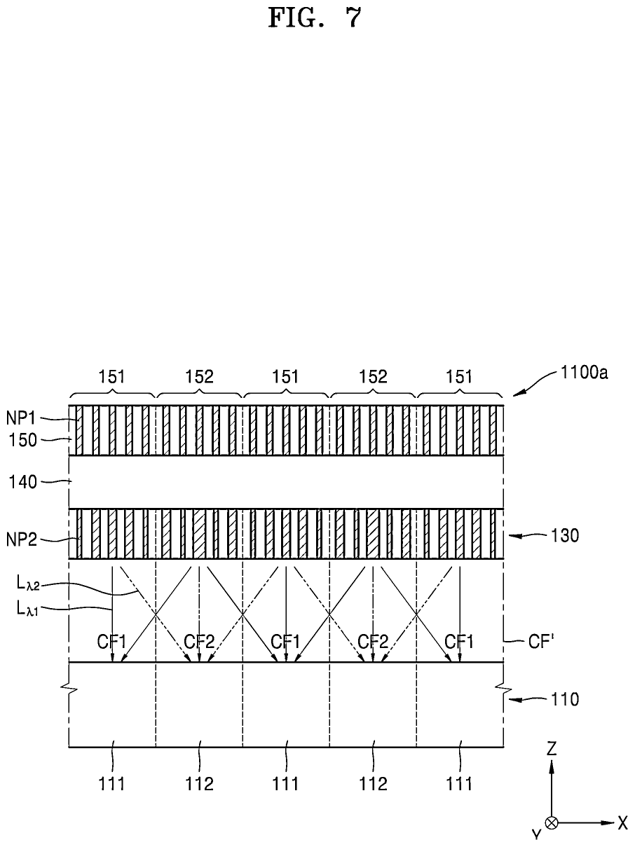

FIG. 7 is a cross-sectional view illustrating another example embodiment of the central portion of the pixel array of the image sensor of FIG. 6A. Differences from FIG. 6A will be mainly described.

Referring to FIG. 7, a color filter layer CF′ including an inorganic material may be provided on or over the sensor substrate 110, and a color separation nanostructure layer 130 may be provided directly on or over the color filter layer CF′ without the first spacer layer 120 of FIG. 6A. The color filter layer CF′ including an inorganic material may have a sufficient thickness to secure the focal length. For convenience, only one cross-section of the central portion 1100a of the pixel array of the image sensor is illustrated; however, the illustration may also be similarly applied other cross-sections of the central portion and the peripheral portion of the pixel array of the image sensor. Alternatively, in another embodiment, a first spacer layer 120 having a smaller thickness than that of FIG. 6A may be provided on or over the color filter layer CF′ including an inorganic material.

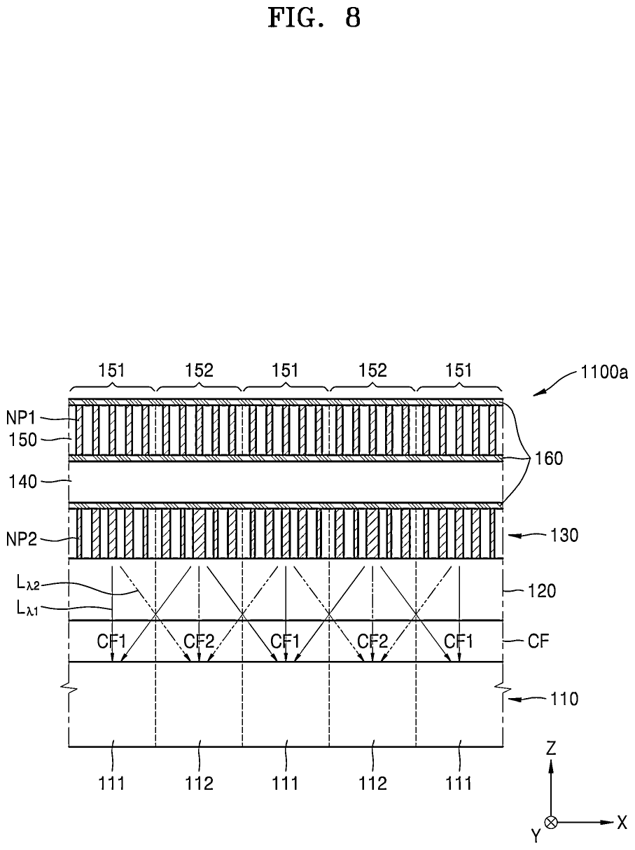

FIG. 8 is a cross-sectional view illustrating another example embodiment of the central portion of the pixel array of the image sensor of FIG. 6A. Differences from FIG. 6A will be mainly described.

Referring to FIG. 8, a pixel array 1100 of the image sensor 1000 may include an anti-reflection layer 160 provided on or over the oblique light compensation layer 150. Also, the pixel array 1100 of the image sensor 1000 may include the anti-reflection layer 160 provided between the oblique light compensation layer 150 and the second spacer layer 140. Also, the pixel array 1100 may include the anti-reflection layer 160 provided between the second spacer layer 140 and the color separation nanostructure layer 130. Moreover, the anti-reflection layers 160 provided at different positions may include different materials by considering the refractive index difference between the respective layers. Also, the anti-reflection layers 160 provided at different positions may have different thicknesses by considering the refractive index difference between the respective layers. Also, the anti-reflection layer 160 may have a hole pattern, and the effective refractive index thereof may be adjusted through the hole pattern and a material filling the hole.

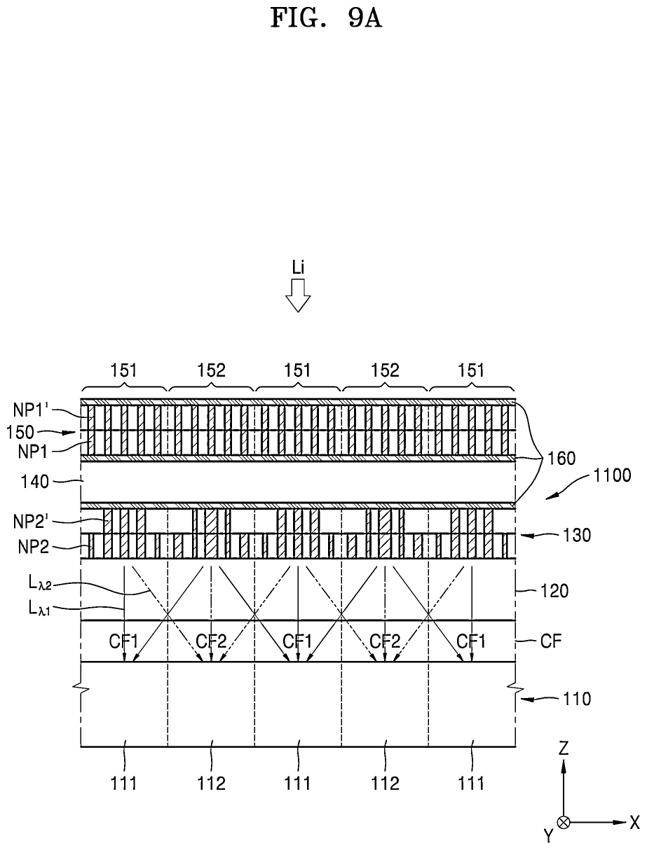

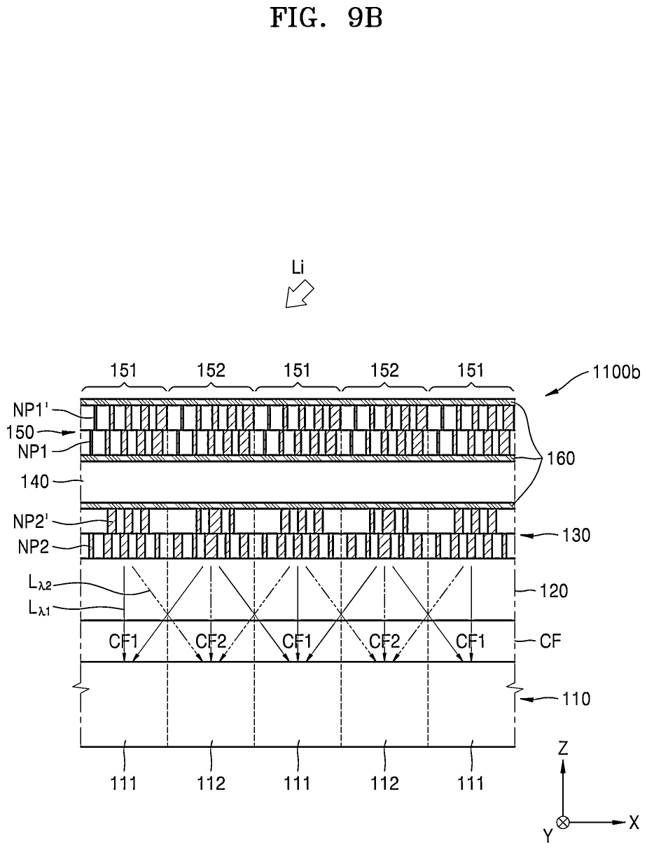

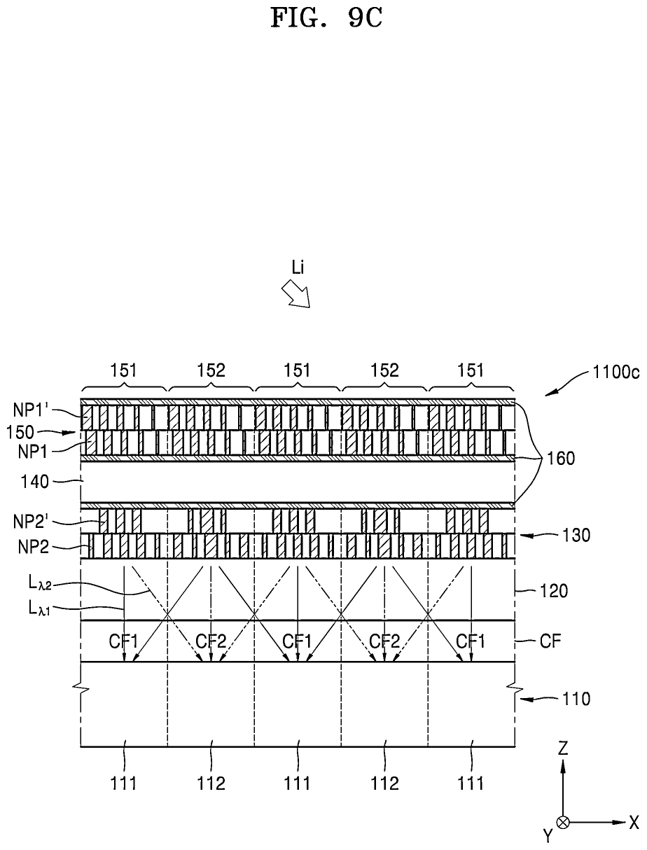

FIGS. 9A to 9C are cross-sectional views illustrating another example embodiment of a central portion and peripheral portion of a pixel array of an image sensor. Differences from FIGS. 6A, 6C, and 6E will be mainly described.

Referring to FIG. 9A, an oblique light compensation nanostructure of the oblique light compensation layer 150 may have a multi-layer structure. For example, the oblique light compensation layer 150 may include a first oblique light compensation nanostructure NP1 and a second oblique light compensation nanostructure NP1′ provided on or over the first oblique light compensation nanostructure NP1. The first oblique light compensation nanostructure NP1 and the second oblique light compensation nanostructure NP1′ may be arranged in a multi-layer structure. The multi-layer oblique light compensation nanostructures NP1 and NP1′ may be shifted in the center direction according to the direction of incident light. For example, referring to FIG. 9B, when the direction of incident light is opposite to (or tilted away from) the first direction (e.g., plus (+) X direction), the second oblique light compensation nanostructure NP1′ may be provided apart from the first oblique light compensation nanostructure NP1 by a certain distance in the first direction (e.g., plus (+) X direction). Also, referring to FIG. 90, when the direction of incident light is toward the first direction (e.g., plus (+) X direction), the second oblique light compensation nanostructure NP1′ may be provided apart from the first oblique light compensation nanostructure NP1 by a certain distance in a direction (e.g., minus (−) X direction) opposite to the first direction (e.g., plus (+) X direction).

Also, a color separation nanostructure of the color separation nanostructure layer 130 may have a multi-layer structure. For example, the color separation nanostructure layer 130 may include a first color separation nanostructure NP2 and a second color separation nanostructure NP2′ provided on or over the first color separation nanostructure NP2. The first color separation nanostructure NP2 and the second color separation nanostructure NP2′ may be arranged in a multi-layer structure. The multi-layer color separation nanostructures NP2 and NP2′ may be shifted by a certain distance in the center direction according to the direction of incident light. For example, referring to FIG. 9B, when the direction of incident light is opposite to (or tilted away from) the first direction (e.g., plus (+) X direction), the second color separation nanostructure NP2′ may be provided apart from the first color separation nanostructure NP2 by a certain distance in the first direction (e.g., plus (+) X direction). Also, referring to FIG. 9C, when the direction of incident light is the first direction (e.g., plus (+) X direction), the second color separation nanostructure NP2′ may be provided apart from the first color separation nanostructure NP2 by a certain distance in a direction (e.g., minus (−) X direction) opposite to the first direction (e.g., plus (+) X direction).

Hereinafter, the differences between the plurality of color separation nanostructures NP2 provided in the color separation nanostructure layer 130 of the pixel array 1100 and the plurality of oblique light compensation nanostructures NP1 provided in the oblique light compensation layer 150 will be mainly described.

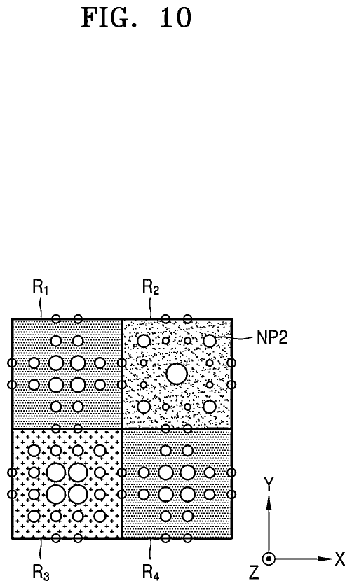

FIG. 10 is a cross-sectional view illustrating a plurality of color separation nanostructures provided in a color separation nanostructure layer of a pixel array according to an example embodiment.

Referring to FIG. 10, as described above, each of the plurality of color separation nanostructures NP2 in each of the first to fourth pixel corresponding areas R₁, R₂, R₃, and R₄ may be provided (or arranged) differently for each wavelength band sensed at the corresponding photosensing cell. The plurality of color separation nanostructures NP2 of the first to fourth pixel corresponding areas R₁, R₂, R₃, and R₄ may be configured to provide different phase profiles for the respective wavelength bands. Moreover, a plurality of color separation nanostructures may be symmetrically arranged in the first direction and the second direction with respect to a center of each of the first to fourth pixel corresponding areas R₁, R₂, R₃, and R₄. Particularly, the color separation nanostructures NP2 arranged in a central area of each of the first to fourth pixel corresponding areas R₁, R₂, R₃, and R₄ may have a greatest diameter such that a greatest phase delay occurs in the central area of each of the first to fourth pixel corresponding areas R₁, R₂, R₃, and R₄, and a diameter of the color separation nanostructure NP2 may decrease gradually away from the central area of each of the first to fourth pixel corresponding areas R₁, R₂, R₃, and R₄. For example, the color separation nanostructures NP2 arranged in an edge area of each of the first to fourth pixel corresponding areas R₁, R₂, R₃, and R₄ may have a smallest diameter. However, the diameter of the color separation nanostructure NP2 arranged in an area where the phase delay is relatively small may not necessarily be relatively small. In the phase profile, a value of the phase delay may be represented as a remainder when divided by 2π; for example, when a phase delay in a certain area is 3π, the phase delay may become optically equal to π remaining after dividing the phase delay by 2π (or subtracting 2π therefrom). Thus, when it is difficult to manufacture due to the small diameter of the color separation nanostructure NP2, the diameter of the color separation nanostructure NP2 may be selected to implement a phase delay increased by 2π. For example, when the diameter of the color separation nanostructure NP2 for achieving a phase delay of 0.1π is too small, the diameter of the color separation nanostructure NP2 may be selected to achieve a phase delay of 2.1π. Thus, in this case, the diameter of the color separation nanostructures NP2 arranged in the edge area of the first to fourth pixel corresponding areas R₁, R₂, R₃, and R₄ may be greatest.

The width and arrangement of the plurality of color separation nanostructures NP2 provided in each of the first to fourth pixel corresponding areas R₁, R₂, R₃, and R₄ may be determined according to the wavelength band of light concentrated on the photosensing cells 111, 112, 113, and 114 corresponding thereto. The width and arrangement of the plurality of color separation nanostructures NP2 provided in each of the first to fourth pixel corresponding areas R₁, R₂, R₃, and R₄ may be the same in the central portion 1100a and peripheral portions 1100b to 1100i of the pixel array 1100. That is, the width and arrangement of the plurality of color separation nanostructures NP2 provided in the first pixel corresponding area R₁ in the central portion 1100a of the pixel array 1100 may be the same as the width and arrangement of the plurality of color separation nanostructures NP2 provided in the first pixel corresponding area R₁ in the peripheral portions 1100b to 1100i of the pixel array 1100. For convenience, the first pixel corresponding area R₁ has been described above as an example, and the above description may also be similarly applied to the second to fourth pixel corresponding areas R₂, R₃, and R₄.

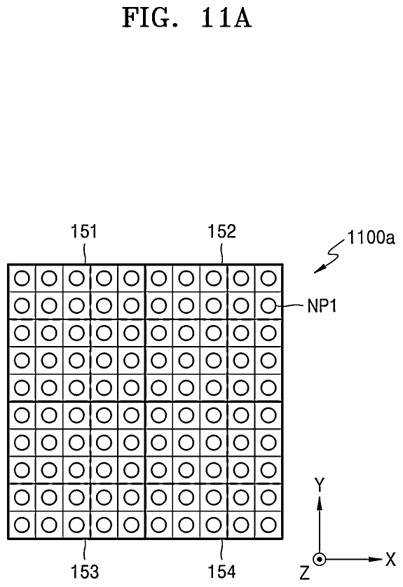

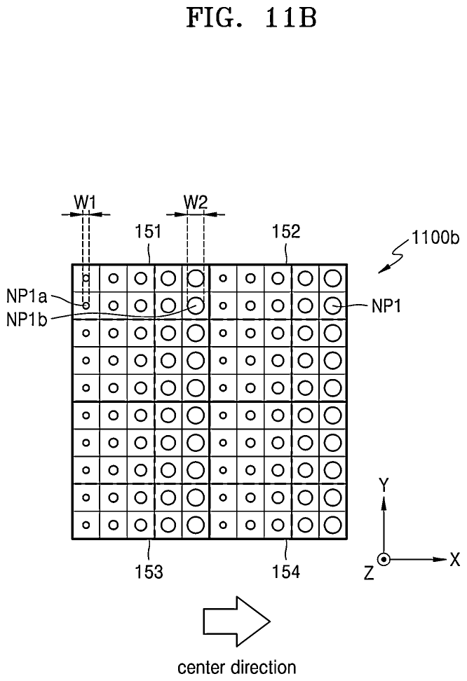

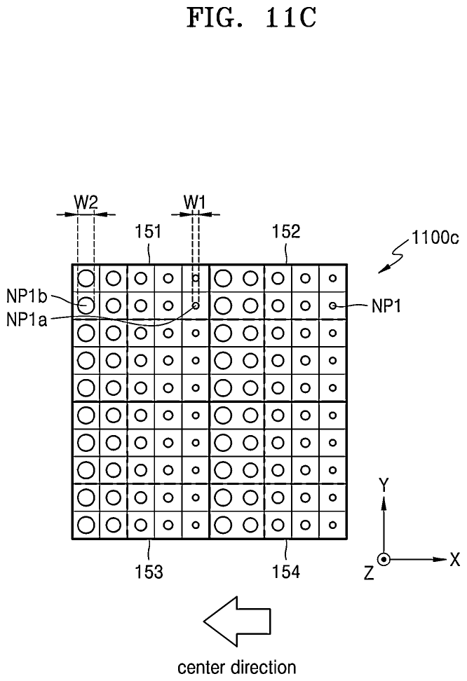

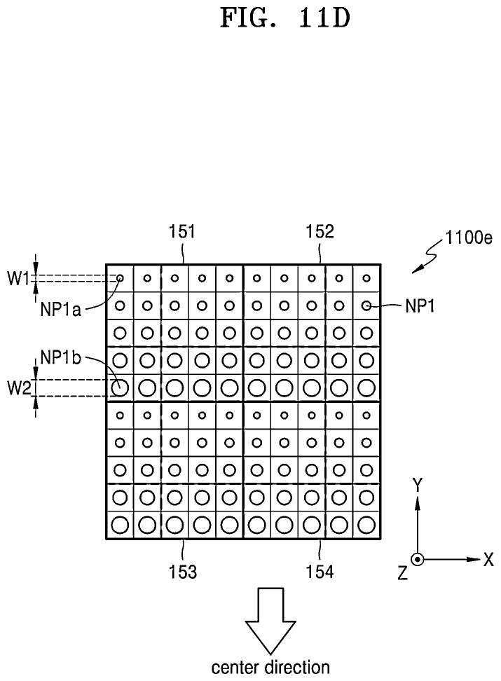

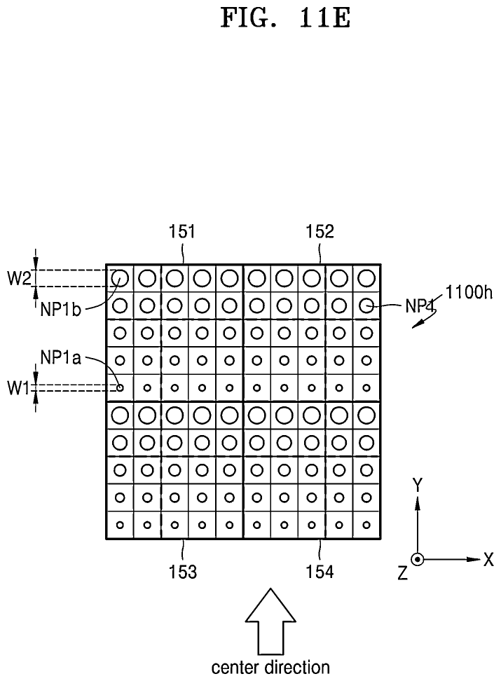

FIG. 11A is a cross-sectional view illustrating an oblique light compensation nanostructure of an oblique light compensation layer in a central portion of a pixel array of an image sensor according to an embodiment, and FIGS. 11B to 11E are cross-sectional views illustrating an oblique light compensation nanostructure of an oblique light compensation layer in a central portion of a pixel array of an image sensor according to an embodiment.

Because it is not necessary to change the propagation direction of incident light in the central portion 1100a of the pixel array 1100, a plurality of oblique light compensation nanostructures NP1 of the oblique light compensation layer 150 provided in the central portion 1100a of the pixel array 1100 may include an oblique light compensation nanostructure NP1 having the same width in each of the first to fourth oblique light compensation areas 151, 152, 153, and 154, as illustrated in FIG. 11A. Also, as illustrated in FIG. 11A, each of the plurality of oblique light compensation nanostructures NP1 of the oblique light compensation layer 150 provided in the central portion 1100a of the pixel array 1100 may be symmetrically provided with respect to the central portion of the first to fourth oblique light compensation areas 151, 152, 153, and 154.

On the other hand, an incident light may be incident at a certain angle with respect to the oblique light compensation layer 150 in the peripheral portions 1100b to 1100i of the pixel array 1100. In other words, the chief ray angle of incident light may be greater than 0 in the peripheral portions 1100b to 1100i of the pixel array 1100. Thus, in the peripheral portions 1100b to 1100i of the pixel array 1100, because a phase difference may occur according to positions as the propagation direction of incident light changes, it may be necessary to change the propagation direction of incident light to compensate oblique light. As illustrated in FIGS. 11B to 11E, a plurality of oblique light compensation nanostructures NP1 of the oblique light compensation layer 150 provided in the peripheral portions 1100b to 1100i of the pixel array 1100 may be configured to change the propagation direction of incident light. The plurality of oblique light compensation nanostructures NP1 may be configured such that the direction of oblique light incident on the oblique light compensation layer 150 is deflected toward the color separation nanostructure layer 130 corresponding thereto.

For example, as for the plurality of oblique light compensation nanostructures NP1 of the oblique light compensation layer 150 provided in the peripheral portions 1100b to 1100i of the pixel array 1100, in each of the first to fourth oblique light compensation areas 151, 152, 153, and 154, the width of an oblique light compensation nanostructure NP1a distant from the central portion 1100a of the pixel array 1100 in the direction of incident light may be smallest and the width of an oblique light compensation nanostructure NP1b close to the central portion 1100a of the pixel array 1100 in the light incidence direction may be greatest.

Also, as the distance between each of the first to fourth oblique light compensation areas 151, 152, 153, and 154 and the central portion 1100a of the pixel array 1100 increases, the difference between the width of the oblique light compensation nanostructure NP1a distant from the central portion 1100a of the pixel array 1100 in the direction of incident light and the width of the oblique light compensation nanostructure NP1b close to the central portion 1100a of the pixel array 1100 in the direction of incident light in each of the first to fourth oblique light compensation areas 151, 152, 153, and 154 may increase.

Referring to FIG. 11B, as for the plurality of oblique light compensation nanostructures NP1 of the oblique light compensation layer 150 provided in the one-side edge 1100b of the pixel array 1100 in the first direction (X direction), in each of the first to fourth oblique light compensation areas 151, 152, 153, and 154, a width W1 of an oblique light compensation nanostructure NP1a distant from the central portion 1100a of the pixel array 1100 in the first direction may be smallest and a width W2 of an oblique light compensation nanostructure NP1b close to the central portion 1100a of the pixel array 1100 in the first direction may be greatest. Also, as the distance between each of the first to fourth oblique light compensation areas 151, 152, 153, and 154 and the central portion 1100a of the pixel array 1100 increases, the difference between the width W1 of the oblique light compensation nanostructure NP1a distant from the central portion 1100a of the pixel array 1100 in the first direction and the width W2 of the oblique light compensation nanostructure NP1b close to the central portion 1100a of the pixel array 1100 in the first direction in each of the first to fourth oblique light compensation areas 151, 152, 153, and 154 may increase. The width of the plurality of oblique light compensation nanostructures NP1 of the oblique light compensation layer 150 provided in the one-side edge 1100b of the pixel array 1100 in the first direction (X direction) may increase toward the central portion 1100a of the pixel array 1100 in the first direction in each of the first to fourth oblique light compensation areas 151, 152, 153, and 154. Also, as illustrated in FIG. 11B, the plurality of oblique light compensation nanostructures NP1 of the oblique light compensation layer 150 provided in the one-side edge 1100b of the pixel array 1100 in the first direction may be symmetrically provided with respect to the direction of incident light (e.g., the X direction) in each of the first to fourth oblique light compensation areas 151, 152, 153, and 154.

Also, referring to FIG. 11C, as for the plurality of oblique light compensation nanostructures NP1 of the oblique light compensation layer 150 provided in the other-side edge 1100c of the pixel array 1100 in the first direction (X direction), in each of the first to fourth oblique light compensation areas 151, 152, 153, and 154, a width W1 of an oblique light compensation nanostructure NP1a distant from the central portion 1100a of the pixel array 1100 in the first direction may be smallest and a width W2 of an oblique light compensation nanostructure NP1b close to the central portion 1100a of the pixel array 1100 in the first direction may be greatest. Also, as the distance between each of the first to fourth oblique light compensation areas 151, 152, 153, and 154 and the central portion 1100a of the pixel array 1100 increases, the difference between the width W1 of the oblique light compensation nanostructure NP1a distant from the central portion 1100a of the pixel array 1100 in the first direction and the width W2 of the oblique light compensation nanostructure NP1b close to the central portion 1100a of the pixel array 1100 in the first direction in each of the first to fourth oblique light compensation areas 151, 152, 153, and 154 may increase. The width of the plurality of oblique light compensation nanostructures NP1 of the oblique light compensation layer 150 provided in the other-side edge 1100c of the pixel array 1100 in the first direction (X direction) may increase toward the central portion 1100a of the pixel array 1100 in the first direction in each of the first to fourth oblique light compensation areas 151, 152, 153, and 154. Also, as illustrated in FIG. 11C, the plurality of oblique light compensation nanostructures NP1 of the oblique light compensation layer 150 provided in the other-side edge 1100c of the pixel array 1100 in the first direction may be symmetrically provided with respect to the direction of incident light (e.g., the X direction) in each of the first to fourth oblique light compensation areas 151, 152, 153, and 154.

Also, referring to FIG. 11D, as for the plurality of oblique light compensation nanostructures NP1 of the oblique light compensation layer 150 provided in the one-side edge 1100e of the pixel array 1100 in the second direction (Y direction), in each of the first to fourth oblique light compensation areas 151, 152, 153, and 154, a width W1 of an oblique light compensation nanostructure NP1a distant from the central portion 1100a of the pixel array 1100 in the second direction may be smallest and a width W2 of an oblique light compensation nanostructure NP1b close to the central portion 1100a of the pixel array 1100 in the second direction may be greatest. Also, as the distance between each of the first to fourth oblique light compensation areas 151, 152, 153, and 154 and the central portion 1100a of the pixel array 1100 increases, the difference between the width W1 of the oblique light compensation nanostructure NP1a distant from the central portion 1100a of the pixel array 1100 in the second direction and the width W2 of the oblique light compensation nanostructure NP1b close to the central portion 1100a of the pixel array 1100 in the second direction in each of the first to fourth oblique light compensation areas 151, 152, 153, and 154 may increase. The width of the plurality of oblique light compensation nanostructures NP1 of the oblique light compensation layer 150 provided in the one-side edge 1100e of the pixel array 1100 in the second direction may increase toward the central portion 1100a of the pixel array 1100 in the second direction in each of the first to fourth oblique light compensation areas 151, 152, 153, and 154. Also, as illustrated in FIG. 11D, the plurality of oblique light compensation nanostructures NP1 of the oblique light compensation layer 150 provided in the one-side edge 1100e of the pixel array 1100 in the second direction may be symmetrically provided with respect to the direction of incident light (e.g., the second direction) in each of the first to fourth oblique light compensation areas 151, 152, 153, and 154.

Also, referring to FIG. 11E, as for the plurality of oblique light compensation nanostructures NP1 of the oblique light compensation layer 150 provided in the other-side edge 1100h of the pixel array 1100 in the second direction (Y direction), in each of the first to fourth oblique light compensation areas 151, 152, 153, and 154, a width W1 of an oblique light compensation nanostructure NP1a distant from the central portion 1100a of the pixel array 1100 in the second direction may be smallest and a width W2 of an oblique light compensation nanostructure NP1b close to the central portion 1100a of the pixel array 1100 in the second direction may be greatest. Also, as the distance between each of the first to fourth oblique light compensation areas 151, 152, 153, and 154 and the central portion 1100a of the pixel array 1100 increases, the difference between the width W1 of the oblique light compensation nanostructure NP1a distant from the central portion 1100a of the pixel array 1100 in the second direction and the width W2 of the oblique light compensation nanostructure NP1b close to the central portion 1100a of the pixel array 1100 in the second direction in each of the first to fourth oblique light compensation areas 151, 152, 153, and 154 may increase. The width of the plurality of oblique light compensation nanostructures NP1 of the oblique light compensation layer 150 provided in the other-side edge 1100h of the pixel array 1100 in the second direction may increase toward the central portion 1100a of the pixel array 1100 in the second direction in each of the first to fourth oblique light compensation areas 151, 152, 153, and 154. Also, as illustrated in FIG. 11E, the plurality of oblique light compensation nanostructures NP1 of the oblique light compensation layer 150 provided in the other-side edge 1100h of the pixel array 1100 in the second direction may be symmetrically provided with respect to the direction of incident light (e.g., the second direction) in each of the first to fourth oblique light compensation areas 151, 152, 153, and 154.

Moreover, the diameter of the oblique light compensation nanostructure NP1 arranged in an area where the phase delay necessary for oblique light compensation is relatively small may not necessarily be relatively small. For example, when a phase delay in a certain area is 3π, the phase delay may become optically equal to π remaining after subtracting 2π therefrom. Thus, when it is difficult to manufacture due to the small diameter of the oblique light compensation nanostructure NP1, the diameter of the oblique light compensation nanostructure NP1 may be selected to implement a phase delay increased by 2π. For example, when the width or diameter of the oblique light compensation nanostructure NP1 for achieving a phase delay of 0.5π is too small, the width or diameter of the oblique light compensation nanostructure NP1 may be selected to achieve a phase delay of 2.5π.

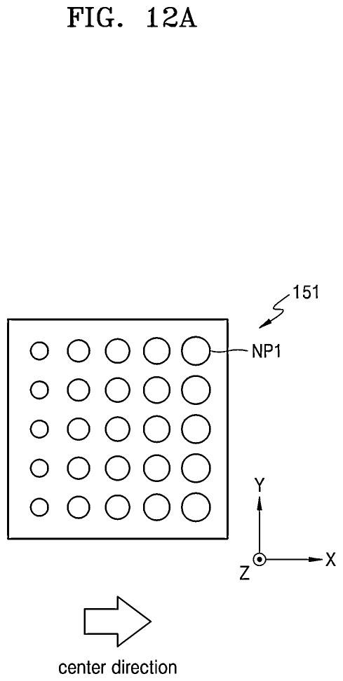

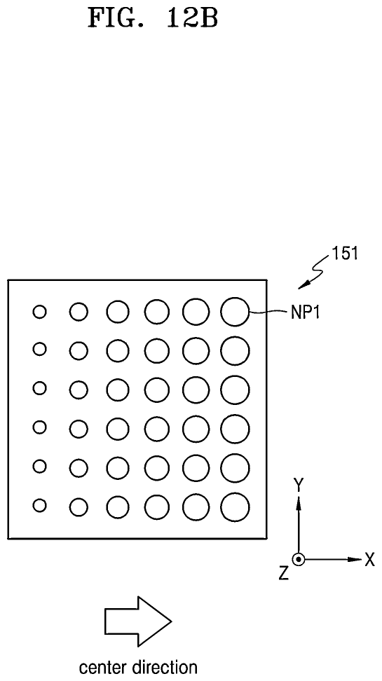

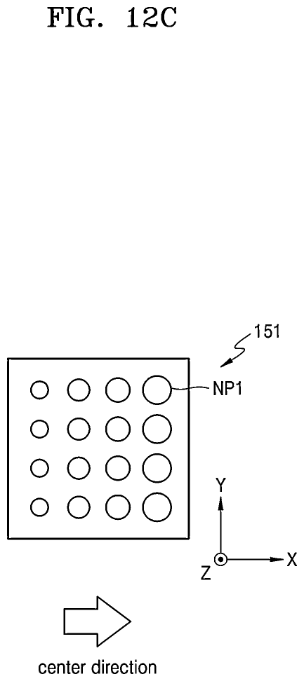

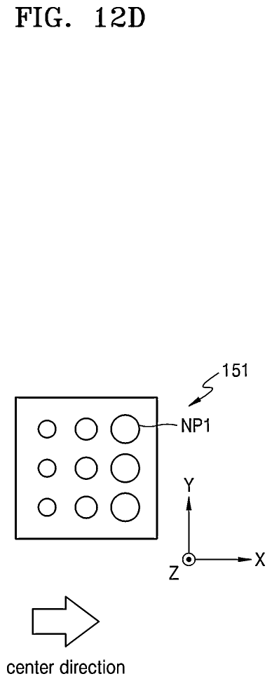

FIGS. 12A to 12D are enlarged views illustrating a plurality of oblique light compensation nanostructures provided in an oblique light compensation layer according to example embodiments.

As in FIG. 12A, a plurality of oblique light compensation nanostructures NP1 are illustrated as being provided in a 5×5 array; however, the plurality of oblique light compensation nanostructures NP1 may be provided in various other arrangements. For example, referring to FIG. 12B, a plurality of oblique light compensation nanostructures NP1 provided in the first oblique light compensation area 151 may be provided in a 6×6 array. Alternatively, referring to FIG. 12C, a plurality of oblique light compensation nanostructures NP1 provided in the first oblique light compensation area 151 may be provided in a 4×4 array. Alternatively, referring to FIG. 12D, a plurality of oblique light compensation nanostructures NP1 provided in the first oblique light compensation area 151 may be provided in a 3×3 array. In FIGS. 12A to 12D, the first oblique light compensation area 151 is illustrated as an example; however, the plurality of oblique light compensation nanostructures NP1 in the second to fourth oblique light compensation areas 152, 153, and 154 may be provided in various arrangements such as a 6×6, 5×5, 4×4, or 3×3 array or any other different arrangements.

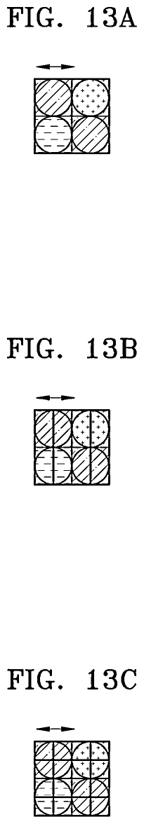

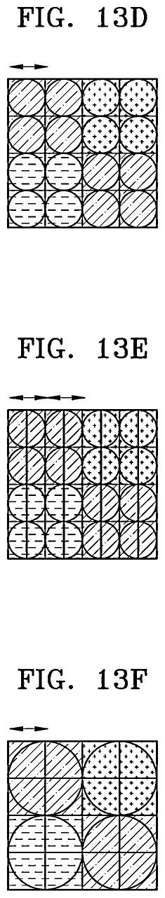

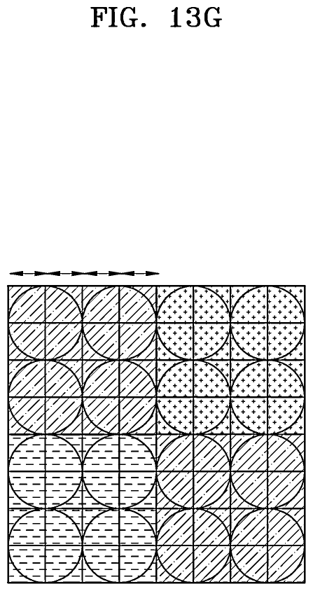

FIGS. 13A to 13G are diagrams conceptually illustrating a pixel array constituting a unit pixel array.

Referring to FIG. 13A, each of the pixels may correspond to one photodiode. Referring to FIG. 13B, each of the pixels may correspond to two photodiodes. Referring to FIG. 13C, each of the pixels may correspond to four photodiodes. Referring to FIG. 13D, each of the pixels may include four subpixels, and each subpixel may correspond to one photodiode. Referring to FIG. 13E, each of the pixels constituting a 2×2 unit pixel array may include four subpixels, and each subpixel may correspond to two photodiodes. Referring to FIG. 13F, four pixels may correspond to one pixel unit. Referring to FIG. 13G, 16 pixels may correspond to one pixel unit. The pixel arrays of FIGS. 13A to 13G may be used to perform an autofocusing function as well as an imaging function.

The image sensor 1000 according to example embodiments described above may have almost no light loss due to a color filter, for example, an organic color filter, and may provide a sufficient amount of light to the pixel even when the size of the pixel becomes small. Thus, an ultra-high resolution, ultra-small, and highly-sensitive image sensor having hundreds of millions of pixels or more may be manufactured. The ultra-high resolution, ultra-small, and highly-sensitive image sensor may be employed in various high-performance optical apparatuses or high-performance electronic apparatuses. The electronic apparatuses may include, for example, smart phones, mobile phones, cellular phones, personal digital assistants (PDAs), laptop computers, personal computers (PCs), various portable devices, home appliances, security cameras, medical cameras, automobiles, Internet of Things (IoT) devices, augmented reality (AR) apparatuses, virtual reality (VR) apparatuses, extended reality (XR) apparatuses expanding the experience of users, or other mobile or non-mobile computing apparatuses but are not limited thereto.

The electronic apparatuses may further include, in addition to the image sensor 1000, a processor for controlling the image sensor, for example, an application processor (AP), and may control a plurality of hardware or software elements and may perform various data processes and operations by driving an operating system or application programs via the processor. The processor may further include a graphic processing unit (GPU) and/or an image signal processor. When an image signal processor is included in the processor, an image (or video) obtained by the image sensor may be stored and/or output by using the processor.

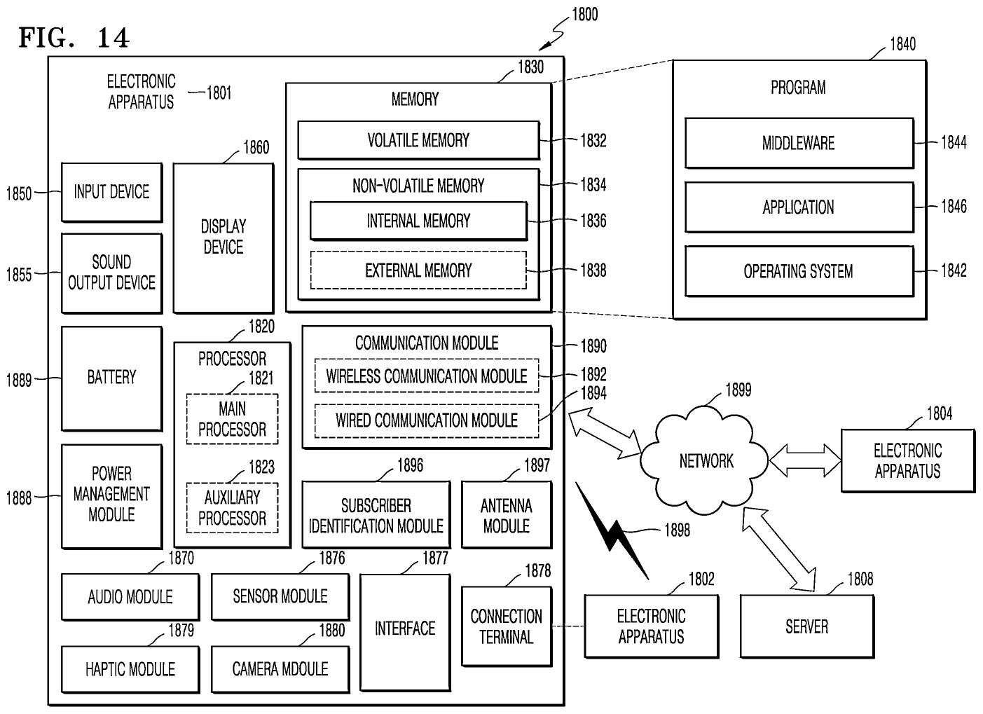

FIG. 14 is a block diagram illustrating an example of an electronic apparatus including an image sensor.

Referring to FIG. 14, in a network environment 1800, an electronic apparatus 1801 may communicate with another electronic apparatus 1802 via a first network 1898 (e.g., short-range wireless communication network or the like), or may communicate with another electronic apparatus 1804 and/or a server 1808 via a second network 1899 (e.g., long-range wireless communication network or the like).

The electronic apparatus 1801 may communicate with the electronic apparatus 1804 via the server 1808. The electronic apparatus 1801 may include a processor 1820, a memory 1830, an input device 1850, a sound output device 1855, a display device 1860, an audio module 1870, a sensor module 1876, an interface 1877, a haptic module 1879, a camera module 1880, a power management module 1888, a battery 1889, a communication module 1890, a subscriber identification module 1896, and/or an antenna module 1897. In the electronic apparatus 1801, some (e.g., display device 1860 or the like) of the elements may be omitted or another element may be added. Some of the elements may be configured as one integrated circuit. For example, the sensor module 1876 (e.g., a fingerprint sensor, an iris sensor, an illuminance sensor, or the like) may be embedded and implemented in the display device 1860 (e.g., display or the like).

The processor 1820 may control one or more elements (e.g., hardware, software elements, or the like) of the electronic apparatus 1801 connected to the processor 1820 by executing software (e.g., program 1840 or the like), and may perform various data processes or operations. As a portion of the data processing or operations, the processor 1820 may load a command and/or data received from another element (e.g., sensor module 1876, communication module 1890, or the like) to a volatile memory 1832, may process the command and/or data stored in the volatile memory 1832, and may store result data in a non-volatile memory 1834. The processor 1820 may include a main processor 1821 (e.g., central processing unit, application processor, or the like) and an auxiliary processor 1823 (e.g., graphic processing unit, image signal processor, sensor hub processor, communication processor, or the like) that may be operated independently from or along with the main processor 1821. The auxiliary processor 1823 may use less power than the main processor 1821 and may perform specialized functions.

The auxiliary processor 1823, on behalf of the main processor 1821 while the main processor 1821 is in an inactive state (e.g., sleep state) or along with the main processor 1821 while the main processor 1821 is in an active state (e.g., application executed state), may control functions and/or states related to some (e.g., display device 1860, sensor module 1876, communication module 1890, or the like) of the elements in the electronic apparatus 1801. The auxiliary processor 1823 (e.g., image signal processor, communication processor, or the like) may be implemented as a portion of another element (e.g., camera module 1880, communication module 1890, or the like) that is functionally related thereto.

The memory 1830 may store various data required by the elements (e.g., processor 1820, sensor module 1876, or the like) of the electronic apparatus 1801. The data may include, for example, input data and/or output data about software (e.g., program 1840 or the like) and commands related thereto. The memory 1830 may include the volatile memory 1832 and/or the non-volatile memory 1834.

The program 1840 may be stored as software in the memory 1830, and may include an operating system 1842, middle ware 1844, and/or an application 1846.

The input device 1850 may receive commands and/or data to be used in the elements (e.g., processor 1820 or the like) of the electronic apparatus 1801, from outside (e.g., user or the like) of the electronic apparatus 1801. The input device 1850 may include a microphone, a mouse, a keyboard, and/or a digital pen (e.g., stylus pen).

The sound output device 1855 may output a sound signal to the outside of the electronic apparatus 1801. The sound output device 1855 may include a speaker and/or a receiver. The speaker may be used for a general purpose such as multimedia reproduction or record play, and the receiver may be used to receive a call. The receiver may be coupled as a portion of the speaker or may be implemented as an independent device.

The display device 1860 may provide visual information to the outside of the electronic apparatus 1801. The display device 1860 may include a display, a hologram device, or a projector, and a control circuit for controlling the corresponding device. The display device 1860 may include a touch circuitry set to sense a touch, and/or a sensor circuit (e.g., pressure sensor or the like) that is set to measure the strength of a force generated by the touch.

The audio module 1870 may convert sound into an electrical signal or vice versa. The audio module 1870 may obtain sound through the input device 1850, or may output sound via the sound output device 1855 and/or a speaker and/or a headphone of another electronic apparatus (e.g., electronic apparatus 1802 or the like) connected directly or wirelessly to the electronic apparatus 1801.

The sensor module 1876 may sense an operating state (e.g., power, temperature, or the like) of the electronic apparatus 1801, or an external environmental state (e.g., user state or the like) and may generate an electrical signal and/or data value corresponding to the sensed state. The sensor module 1876 may include a gesture sensor, a gyro sensor, a pressure sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The interface 1877 may support one or more designated protocols that may be used in order for the electronic apparatus 1801 to be directly or wirelessly connected to another electronic apparatus (e.g., electronic apparatus 1802 or the like). The interface 1877 may include a high-definition multimedia interface (HDMI), a universal serial bus (USB) interface, an SD card interface, and/or an audio interface.

The connection terminal 1878 may include a connector by which the electronic apparatus 1801 may be physically connected to another electronic apparatus (e.g., electronic apparatus 1802 or the like). The connection terminal 1878 may include an HDMI connector, a USB connector, an SD card connector, and/or an audio connector (e.g., headphone connector or the like).

The haptic module 1879 may convert the electrical signal into a mechanical stimulus (e.g., vibration, motion, or the like) or an electrical stimulus that the user may sense through a tactile or motion sensation. The haptic module 1879 may include a motor, a piezoelectric device, and/or an electric stimulus device.

The camera module 1880 may obtain a still image and a video. The camera module 1880 may include a lens assembly including one or more lenses, the image sensor 1000 of FIG. 1, image signal processors, and/or flashes. The lens assembly included in the camera module 1880 may collect light emitted from an object (or subject) that is to be photographed (or captured).

The power management module 1888 may manage the power supplied to the electronic apparatus 1801. The power management module 1888 may be implemented as a portion of a power management integrated circuit (PMIC).

The battery 1889 may supply power to elements of the electronic apparatus 1801. The battery 1889 may include a primary battery that is not rechargeable, a secondary battery that is rechargeable, and/or a fuel cell.

The communication module 1890 may support establishment of a direct (e.g., wired) communication channel and/or a wireless communication channel between the electronic apparatus 1801 and another electronic apparatus (e.g., electronic apparatus 1802, electronic apparatus 1804, server 1808, or the like), and execution of communication through the established communication channel. The communication module 1890 may be operated independently from the processor 1820 (e.g., application processor or the like) and may include one or more communication processors that support the direct communication and/or the wireless communication. The communication module 1890 may include a wireless communication module 1892 (e.g., cellular communication module, a short-range wireless communication module, a global navigation satellite system (GNSS) communication module) and/or a wired communication module 1894 (e.g., local area network (LAN) communication module, a power line communication module, or the like). From among the communication modules, a corresponding communication module may communicate with another electronic apparatus via the first network 1898 (e.g., short-range communication network such as Bluetooth, WiFi direct, or infrared data association (IrDA)) or the second network 1899 (e.g., long-range communication network such as a cellular network, Internet, or computer network (e.g., LAN, WAN, or the like)). Such various kinds of communication modules may be integrated as one element (e.g., single chip or the like) or may be implemented as a plurality of elements (e.g., a plurality of chips) separately from one another. The wireless communication module 1892 may identify and authenticate the electronic apparatus 1801 in a communication network such as the first network 1898 and/or the second network 1899 by using subscriber information (e.g., international mobile subscriber identifier (IMSI) or the like) stored in the subscriber identification module 1896.

The antenna module 1897 may transmit/receive the signal and/or power to/from the outside (e.g., another electronic apparatus or the like). An antenna may include a radiator formed as a conductive pattern formed on a substrate (e.g., PCB or the like). The antenna module 1897 may include one or more antennas. When the antenna module 1897 includes a plurality of antennas, from among the plurality of antennas, an antenna that is suitable for the communication mode used in the communication network such as the first network 1898 and/or the second network 1899 may be selected by the communication module 1890. The signal and/or the power may be transmitted between the communication module 1890 and another electronic apparatus via the selected antenna. Another component (e.g., RFIC or the like) other than the antenna may be included as a portion of the antenna module 1897.

Some of the elements may be connected to each other via the communication method among the peripheral devices (e.g., bus, general purpose input and output (GPIO), serial peripheral interface (SPI), mobile industry processor interface (MIPI), or the like) and may exchange signals (e.g., commands, data, or the like) with each other.

The command or data may be transmitted or received between the electronic apparatus 1801 and the external electronic apparatus 1804 via the server 1808 connected to the second network 1899. Other electronic apparatuses 1802 and 1804 may be apparatuses that are the same as or different types from the electronic apparatus 1801. All or some of the operations executed in the electronic apparatus 1801 may be executed in one or more apparatuses among the other electronic apparatuses 1802, 1804, and 1808. For example, when the electronic apparatus 1801 has to perform a certain function or service, the electronic apparatus 1801 may request one or more other electronic apparatuses to perform some or all of the function or service, instead of executing the function or service by itself. One or more electronic apparatuses receiving the request may execute an additional function or service related to the request and may transmit the result of the execution to the electronic apparatus 1801. For this purpose, for example, a cloud computing, a distributed computing, or a client-server computing technique may be used.

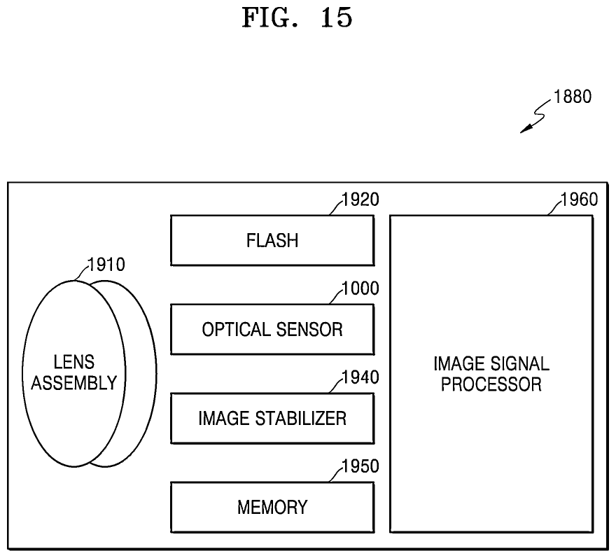

FIG. 15 is a block diagram illustrating an example of the camera module of FIG. 14.

Referring to FIG. 15, the camera module 1880 may include a lens assembly 1910, a flash 1920, an image sensor 1000 (see FIG. 1), an image stabilizer 1940, a memory 1950 (e.g., buffer memory or the like), and/or an image signal processor 1960. The lens assembly 1910 may collect light emitted from an object, that is, an object to be photographed. The camera module 1880 may include a plurality of lens assemblies 1910, and in this case, the camera module 1880 may include a dual camera module, a 360-degree camera, or a spherical camera. Some of the plurality of lens assemblies 1910 may have the same lens properties (e.g., viewing angle, focal length, autofocus, F number, optical zoom, or the like) or may have different lens properties. The lens assembly 1910 may include a wide-angle lens or a telephoto lens.

The flash 1920 may emit light that is used to strengthen the light emitted or reflected from the object. The flash 1920 may include one or more light emitting diodes (e.g., red-green-blue (RGB) LED, white LED, infrared LED, ultraviolet LED, or the like), and/or a Xenon lamp. The image sensor 1000 may be the image sensor described above with reference to FIG. 1 and may convert the light emitted or reflected from the object and transmitted through the lens assembly 1910 into an electrical signal to obtain an image corresponding to the object. The image sensor 1000 may include one or more selected sensors from among image sensors having different properties, such as an RGB sensor, a black-and-white (BW) sensor, an IR sensor, and/or a UV sensor. Each of the sensors included in the image sensor 1000 may be implemented as a charge coupled device (CCD) sensor and/or a complementary metal oxide semiconductor (CMOS) sensor.

In response to a motion of the camera module 1880 or the electronic apparatus 1801 including the camera module 1880, the image stabilizer 1940 may move one or more lenses included in the lens assembly 1910 or the image sensor 1000 in a certain direction or may control the operation characteristics of the image sensor 1000 (e.g., adjusting of a read-out timing or the like) to compensate for a negative influence of the motion. The image stabilizer 1940 may sense the movement of the camera module 1880 or the electronic apparatus 1801 by using a gyro sensor (not illustrated) or an acceleration sensor (not illustrated) arranged inside or outside the camera module 1880. The image stabilizer 1940 may be implemented as an optical type.

The memory 1950 may store some or all data of the image obtained through the image sensor 1000 for next image processing operation. For example, when a plurality of images are obtained at a high speed, obtained original data (e.g., Bayer-patterned data, high-resolution data, or the like) may be stored in the memory 1950 and only a low-resolution image may be displayed and then original data of a selected image (e.g., user selection or the like) may be transmitted to the image signal processor 1960. The memory 1950 may be integrated with the memory 1830 of the electronic apparatus 1801 or may include a separate memory that is operated independently.

The image signal processor 1960 may perform image processing on the image obtained through the image sensor 1000 or the image data stored in the memory 1950. The image processing may include depth map generation, three-dimensional modeling, panorama generation, feature extraction, image synthesis, and/or image compensation (e.g., noise reduction, resolution adjustment, brightness adjustment, blurring, sharpening, softening, or the like). The image signal processor 1960 may perform controlling (e.g., exposure time control, read-out timing control, or the like) of the elements (e.g., image sensor 1000 or the like) included in the camera module 1880. The image processed by the image signal processor 1960 may be stored again in the memory 1950 for additional process, or may be provided to an external element of the camera module 1880 (e.g., the memory 1830, the display device 1860, the electronic apparatus 1802, the electronic apparatus 1804, the server 1808, or the like). The image signal processor 1960 may be integrated with the processor 1820 or may be configured as a separate processor that is operated independently from the processor 1820. When the image signal processor 1960 is configured as a separate processor separately from the processor 1820, the image processed by the image signal processor 1960 may undergo additional image processing by the processor 1820 and then may be displayed on the display device 1860.

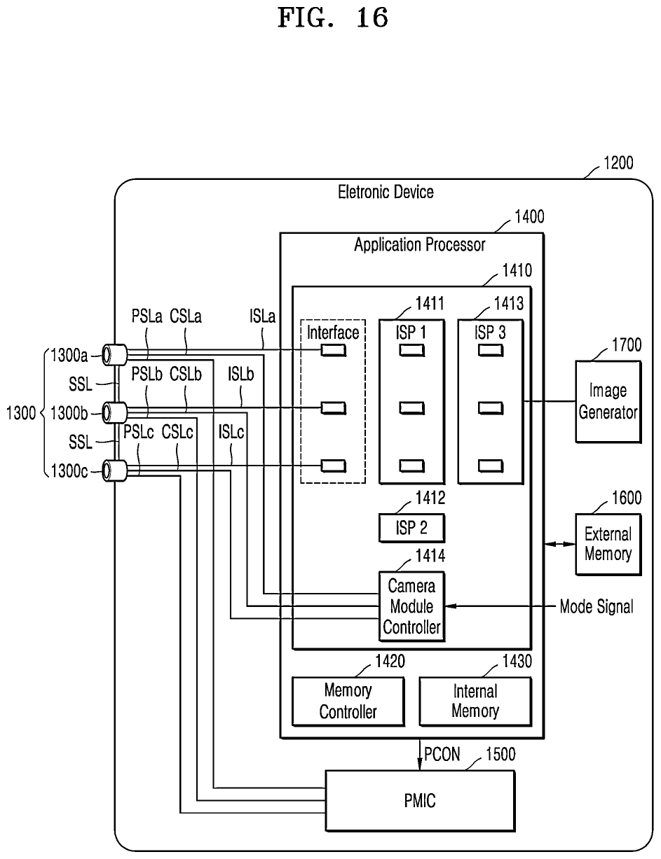

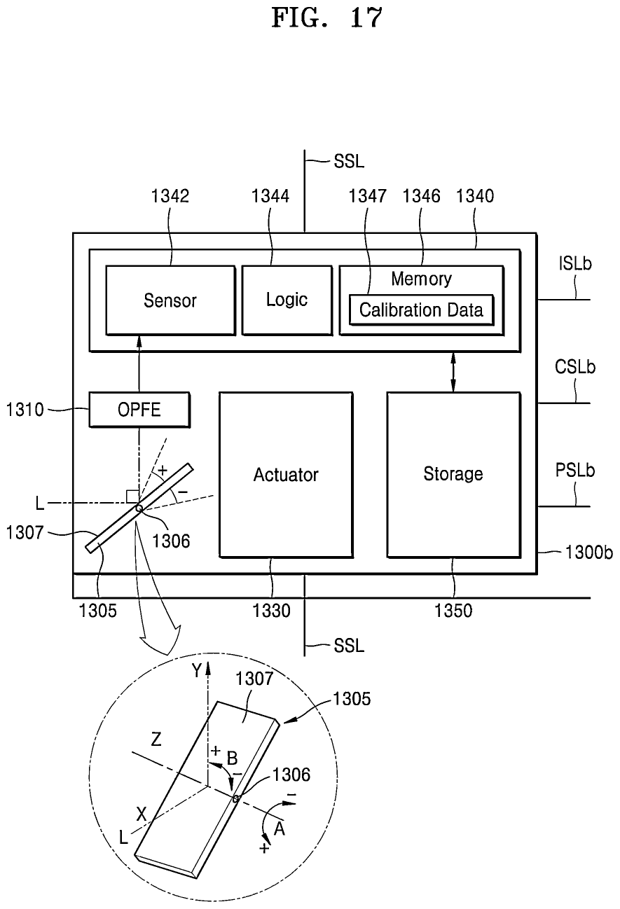

FIG. 16 is a block diagram of an electronic apparatus including a multi-camera module; and FIG. 17 is a detailed block diagram of a camera module of the electronic apparatus illustrated in FIG. 16.

Referring to FIG. 16, an electronic apparatus 1200 may include a camera module group 1300, an application processor 1400, a power management integrated circuit (PMIC) 1500, an external memory 1600, and an image generator 1700.

The camera module group 1300 may include a plurality of camera modules 1300a, 1300b, and 1300c. Although an embodiment in which three camera modules 1300a, 1300b, and 1300c are arranged is illustrated, the present embodiments are not limited thereto. In some embodiments, the camera module group 1300 may be modified to include only two camera modules. Also, in some embodiments, the camera module group 1300 may be modified to include n camera modules (“n” is a natural number greater than or equal to 4).

Hereinafter, a detailed configuration of the camera module 1300b will be described in more detail with reference to FIG. 17; however, the following description may also be similarly applied to other camera modules 1300a and 1300c according to embodiments.

Referring to FIG. 17, the camera module 1300b may include a prism 1305, an optical path folding element (OPFE) 1310, an actuator 1330, an image sensing device 1340, and a storage 1350.

The prism 1305 may include a reflection surface 1307 of a light reflecting material and may change the path of light L incident from the outside.

In some embodiments, the prism 1305 may change the path of light L incident in a first direction X into a second direction Y perpendicular to the first direction X. Also, the prism 1305 may rotate the reflection surface 1307 of a light reflecting material in a direction A around a central axis 1306 or may rotate the central axis 1306 in a direction B to change the path of light L incident in the first direction X into the second direction Y perpendicular thereto. In this case, the OPFE 1310 may also move in a third direction Z perpendicular to the first direction X and the second direction Y.

In some embodiments, as illustrated, the maximum rotation angle of the prism 1305 in the direction A may be less than or equal to 15 degrees in the plus (+) A direction and may be greater than 15 degrees in the minus (−) A direction; however, the present embodiments are not limited thereto.

In some embodiments, the prism 1305 may move by about 20 degrees in the plus (+) or minus (−) B direction, or between 10 degrees and 20 degrees, or between 15 degrees and 20 degrees, where the prism 1305 may move by the same angle in the plus (+) or minus (−) B direction or may move by a substantially similar angle within a range of about 1 degrees.

In some embodiments, the prism 1305 may move the reflection surface 1307 of a light reflecting material in a third direction (e.g., Z direction) parallel to the extension direction of the central axis 1306.

The OPFE 1310 may include, for example, a group of m optical lenses (where “m” is a natural number). The m optical lenses may change the optical zoom ratio of the camera module 1300b by moving in the second direction Y. For example, assuming that the basic optical zoom ratio of the camera module 1300b is Z, when the m optical lenses included in the OPFE 1310 are moved, the optical zoom ratio of the camera module 1300b may be changed into 3Z or 5Z or 10Z or more.

The actuator 1330 may move the OPFE 1310 or an optical lens to a particular position. For example, the actuator 1330 may adjust the position of the optical lens such that an image sensor 1342 is located at the focal length of the optical lens for accurate sensing.

The image sensing device 1340 may include an image sensor 1342, control logic 1344, and a memory 1346. The image sensor 1342 may sense an image of a sensing target by using the light L provided through the optical lens. The control logic 1344 may control an overall operation of the camera module 1300b. For example, the control logic 1344 may control an operation of the camera module 1300b according to a control signal provided through a control signal line CSLb.

As an example, the image sensor 1342 may refer to the image sensor 1000 described above. The image sensor 1342 may receive more signals separated by the wavelength for each pixel by including a color separation nanostructure layer including color separation nanostructures and an oblique light compensation layer including oblique light compensation nanostructures. Due to this effect, the amount of light required to generate a high-quality image at high resolution and low illuminance may be secured.

The memory 1346 may store information necessary for the operation of the camera module 1300b, such as calibration data 1347. The calibration data 1347 may include information necessary to generate image data by using the light L provided from the outside through the camera module 1300b. The calibration data 1347 may include, for example, information about the degree of rotation, information about the focal length, and information about the optical axis described above. When the camera module 1300b is implemented as a multi-state camera of which a focal length changes according to the position of the optical lens, the calibration data 1347 may include the focal length value of the optical lens for each position (or state) and information related to autofocusing.

The storage 1350 may store the image data sensed through the image sensor 1342. The storage 1350 may be arranged outside the image sensing device 1340 and may be implemented in a stacked form with a sensor chip constituting the image sensing device 1340. In some embodiments, the storage 1350 may be implemented as an electrically erasable programmable read-only memory (EEPROM); however, the present embodiments are not limited thereto.

Referring to FIGS. 16 and 17, in some embodiments, each of a plurality of camera modules 1300a, 1300b, and 1300c may include an actuator 1330. Accordingly, each of the plurality of camera modules 1300a, 1300b, and 1300c may include the same or different calibration data 1347 according to an operation of the actuator 1330 included therein.

In some embodiments, one camera module (e.g., 1300b) among the plurality of camera modules 1300a, 1300b, and 1300c may be a folded lens type camera module including the prism 1305 and the OPFE 1310 described above, and the other camera modules (e.g., 1300a and 1300b) may be vertical type camera modules not including the prism 1305 and the OPFE 1310; however, the present embodiments are limited thereto.

In some embodiments, one camera module (e.g., 1300c) among the plurality of camera modules 1300a, 1300b, and 1300c may include a vertical type depth camera that extracts depth information by using, for example, infrared ray (IR).

In some embodiments, at least two camera modules (e.g., 1300a and 1300b) among the plurality of camera modules 1300a, 1300b, and 1300c may have different fields of view. In this case, for example, the optical lenses of at least two camera modules (e.g., 1300a and 1300b) among the plurality of camera modules 1300a, 1300b, and 1300c may be different from each other; however, the disclosure is not limited thereto.

Also, in some embodiments, the respective fields of view of the plurality of camera modules 1300a, 1300b, and 1300c may be different from each other. In this case, the optical lenses respectively included in the plurality of camera modules 1300a, 1300b, and 1300c may also be different from each other; however, the disclosure is not limited thereto.

In some embodiments, the plurality of camera modules 1300a, 1300b, and 1300c may be arranged to be physically separated from each other. That is, instead of the sensing area of one image sensor 1342 being divided and used by the plurality of camera modules 1300a, 1300b, and 1300c, an independent image sensor 1342 may be arranged in each of the multiple camera modules 1300a, 1300b, and 1300c.

Referring back to FIG. 16, the application processor 1400 may include an image processing device 1410, a memory controller 1420, and an internal memory 1430. The application processor 1400 may be implemented separately from the plurality of camera modules 1300a, 1300b, and 1300c. For example, the application processor 1400 and the plurality of camera modules 1300a, 1300b, and 1300c may be implemented separately as separate semiconductor chips.

The image processing device 1410 may include a plurality of image processors 1411, 1412, and 1413, and a camera module controller 1414.

Image data generated respectively from the camera modules 1300a, 1300b, and 1300c may be provided to the image processing device 1410 respectively through image signal lines ISLa, ISLb, and ISLc that are separated from each other. The image data may be transmitted by using, for example, a camera serial interface (CSI) based on a mobile industry processor interface (MIPI); however, the present embodiments are not limited thereto.

The image data transmitted to the image processing device 1410 may be stored in the external memory 1600 before being transmitted to the image processors 1411 and 1412. The image data stored in the external memory 1600 may be provided to the image processor 1411 and/or the image processor 1412. The image processor 1411 may correct the received image data to generate a video. The image processor 1412 may correct the received image data to generate a still image. For example, the image processors 1411 and 1412 may perform a preprocessing operation such as color correction and gamma correction on the image data.

The image processor 1411 may include subprocessors. When the number of subprocessors is equal to the number of camera modules 1300a, 1300b, and 1300c, each of the subprocessors may process the image data provided from one camera module. When the number of subprocessors is less than the number of camera modules 1300a, 1300b, and 1300c, at least one of the subprocessors may process the image data provided from a plurality of camera modules by using a time-sharing process. The image data processed by the image processor 1411 and/or the image processor 1412 may be stored in the external memory 1600 before being transmitted to the image processor 1413. The image data stored in the external memory 1600 may be transmitted to the image processor 1413. The image processor 1413 may perform a postprocessing operation such as noise correction and sharpening correction on the image data.

The image data processed by the image processor 1413 may be provided to the image generator 1700. According to image generation information or a mode signal, the image generator 1700 may generate a final image by using the image data provided from the image processor 1413.

Particularly, according to image generation information or a mode signal, the image generator 1700 may generate an output image by merging at least some of the image data generated from the camera modules 1300a, 1300b, and 1300c with different fields of view. Also, according to image generation information or a mode signal, the image generator 1700 may select at least one of the image data generated from the camera modules 1300a, 1300b, and 1300c with different fields of view.

In some embodiments, the image generation information may include a zoom signal or a zoom factor. Also, in some embodiments, the mode signal may be, for example, a signal based on the mode selected by the user.

When the image generation information is a zoom signal (e.g., zoom factor) and the camera modules 1300a, 1300b, and 1300c have different observation fields (e.g., fields of view), the image generator 1700 may perform different operations depending on the types of the zoom signal. For example, when the zoom signal is a first signal, the image data output from the camera module 1300a and the image data output from the camera module 1300c may be merged and then an output image may be generated by using the merged image signal and the image data that is output from the camera module 1300b but is not used for merging. When the zoom signal is a second signal different from the first signal, the image generator 1700 may generate an output image by selecting one of the image data output respectively from the camera module 1300a, 1300b, and 1300c without merging the image data. However, the present embodiments are not limited thereto, and a method of processing the image data may be variously modified as necessary.

The camera module controller 1414 may provide control signals to the camera modules 1300a, 1300b, and 1300c respectively. The control signals generated from the camera module controller 1414 may be respectively provided to the camera modules 1300a, 1300b, and 1300c corresponding thereto through the control signal lines CSLa, CSLb, and CSLc separated from each other.

In some embodiments, the control signals provided from the camera module controller 1414 to the plurality of camera modules 1300a, 1300b, and 1300c may include mode information according to the mode signal. Based on the mode information, the plurality of camera modules 1300a, 1300b, and 1300c may operate in a first operation mode and a second operation mode in relation to a sensing speed.

In the first operation mode, the plurality of camera modules 1300a, 1300b, and 1300c may generate an image signal at a first rate (e.g., generate an image signal of a first frame rate), encode the image signal at a second rate higher than the first rate (e.g., encode the image signal of a second frame rate higher than the first frame rate), and transmit the encoded image signal to the application processor 1400. In this case, the second rate may be less than or equal to 30 times the first rate.

The application processor 1400 may store the received image signal, that is, the encoded image signal, in the internal memory 1430 or the external memory 1600 of the application processor 1400 and then read the encoded image signal from the internal memory 1430 or the external memory 1600, decode the encoded image signal, and display image data generated based on the decoded image signal. For example, the image processors 1411 and 1412 of the image processing device 1410 may perform decoding and may also perform image processing on the decoded image signal.

In the second operation mode, the plurality of camera modules 1300a, 1300b, and 1300c may generate an image signal at a third rate lower than the first rate (e.g., generate an image signal at a third frame rate lower than the first frame rate) and transmit the image signal to the application processor 1400. The image signal provided to the application processor 1400 may be an unencoded signal. The application processor 1400 may perform image processing on the received image signal or store the image signal in the internal memory 1430 or the external memory 1600.

The PMIC 1500 may supply power, for example, a power voltage, to each of the plurality of camera modules 1300a, 1300b, and 1300c. For example, under the control by the application processor 1400, the PMIC 1500 may supply first power to the camera module 1300a through a power signal line PSLa, supply second power to the camera module 1300b through a power signal line PSLb, and supply third power to the camera module 1300c through a power signal line PSLc.

In response to a power control signal PCON from the application processor 1400, the PMIC 1500 may generate power corresponding to each of the plurality of camera modules 1300a, 1300b, and 1300c and may also adjust the level of the power. The power control signal PCON may include a power adjustment signal for each operation mode of the plurality of camera modules 1300a, 1300b, and 1300c. For example, the operation mode may include a low power mode, and in this case, the power control signal PCON may include information about the camera module operating in the low power mode and the set power level. The levels of the power provided respectively to the plurality of camera modules 1300a, 1300b, and 1300c may be equal to or different from each other. Also, the level of the power may be dynamically changed.

The image sensor according to the described embodiments may separate incident light according to wavelengths thereof by using a color separation nanostructure layer and concentrate each separate light on a photosensing cell sensing a corresponding wavelength among photosensing cells.

Also, the image sensor according to the described embodiments may use an oblique light compensation layer to change an incidence angle of incident light incident with a great chief ray angle at an edge of the image sensor to be close to a perpendicular angle. Particularly, the oblique light compensation layer may include a plurality of nanostructures by considering changes in the chief ray angle depending on various positions on the image sensor. Accordingly, the sensitivity of pixels located at the edge of the image sensor may be improved to be similar to the sensitivity of pixels located in a central portion of the image sensor.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An image sensor comprising:
a sensor substrate comprising a plurality of photosensing cells, each of the plurality of photosensing cells being configured to sense a light;
a color separation nanostructure layer provided on the sensor substrate and comprising a plurality of color separation nanostructures, each of the plurality of color separation nanostructures being configured to separate the light according to wavelengths and concentrate each separated light on a corresponding photosensing cell among the plurality of photosensing cells;
a spacer layer provided on the color separation nanostructure layer; and
an oblique light compensation layer provided on the spacer layer and comprising a plurality of oblique light compensation nanostructures,
wherein the plurality of color separation nanostructures are arranged differently for each wavelength band that is sensed by the corresponding photosensing cell, and an arrangement of the plurality of color separation nanostructures provided in a peripheral portion of the color separation nanostructure layer is same as an arrangement of the plurality of color separation nanostructures provided in a central portion of the color separation nanostructure layer, and
wherein the plurality of oblique light compensation nanostructures are configured such that a direction of an oblique light incident on the oblique light compensation layer is deflected toward the color separation nanostructure layer corresponding thereto, the plurality of oblique light compensation nanostructures are arranged differently for each position of the oblique light compensation layer, and a thickness of the spacer layer is about 1 time to about 3 times a longest wavelength among wavelengths of the light sensed by the plurality of photosensing cells.

2. The image sensor of claim 1, wherein in a central portion of the oblique light compensation layer, the plurality of oblique light compensation nanostructures have a same width, and
wherein in a peripheral portion of the oblique light compensation layer, in an area corresponding to each photosensing cell, a width of an oblique light compensation nanostructure closer to the central portion of the oblique light compensation layer is greater than a width of an oblique light compensation nanostructure distant from the central portion of the oblique light compensation layer.

3. The image sensor of claim 1, wherein, as a distance between an oblique light compensation nanostructure and a central portion of the oblique light compensation layer increases, a difference between a width of an oblique light compensation nanostructure closer to the central portion of the oblique light compensation layer and a width of an oblique light compensation nanostructure distant from the central portion of the oblique light compensation layer, in an area corresponding to each photosensing cell, increases.

4. The image sensor of claim 1, wherein the plurality of oblique light compensation nanostructures are symmetrically arranged with respect to a direction in which the light is incident on the oblique light compensation layer, in an area corresponding to each photosensing cell.

5. The image sensor of claim 4, wherein the plurality of oblique light compensation nanostructures of the oblique light compensation layer on which the light is incident in a first direction are symmetrically arranged with respect to the first direction in the area corresponding to each photosensing cell, and the plurality of oblique light compensation nanostructures of the oblique light compensation layer on which the light is incident in a second direction are symmetrically arranged with respect to the second direction in the area corresponding to each photosensing cell.

6. The image sensor of claim 1, further comprising a color filter layer arranged between the sensor substrate and the color separation nanostructure layer and comprising a plurality of filters, each of which is configured to transmit only a light in a particular wavelength band and absorb or reflect light in other wavelength bands.

7. The image sensor of claim 1, further comprising another spacer layer provided between the sensor substrate and the color separation nanostructure layer, wherein a thickness of the another spacer layer provided between the sensor substrate and the color separation nanostructure layer is determined based on a focal length of the color separation nanostructure layer.

8. The image sensor of claim 7, wherein the thickness of the another spacer layer provided between the sensor substrate and the color separation nanostructure layer is about 1.5 times to about 5 times a longest wavelength among wavelengths of a light incident on the color separation nanostructure layer.

9. The image sensor of claim 1, further comprising an anti-reflection layer provided on the oblique light compensation layer in at least one of between the oblique light compensation layer and the spacer layer or between the spacer layer and the color separation nanostructure layer.

10. The image sensor of claim 1, wherein each of the plurality of oblique light compensation nanostructures comprises a first oblique light compensation nanostructure and a second oblique light compensation nanostructure provided on the first oblique light compensation nanostructure, the first oblique light compensation nanostructure and the second oblique light compensation nanostructure being provided in a multi-layer structure, and
wherein each of the plurality of color separation nanostructures comprises a first color separation nanostructure and a second color separation nanostructure provided on the first color separation nanostructure, the first color separation nanostructure and the second color separation nanostructure being provided in a multi-layer structure.

11. The image sensor of claim 1, wherein each of the plurality of oblique light compensation nanostructures comprises a first oblique light compensation nanostructure and a second oblique light compensation nanostructure provided on the first oblique light compensation nanostructure, the first oblique light compensation nanostructure and the second oblique light compensation nanostructure being provided in a multi-layer structure, and the second oblique light compensation nanostructure being closer to a central portion of the oblique light compensation layer than the first oblique light compensation nanostructure.

12. The image sensor of claim 1, wherein at least one of the plurality of color separation nanostructures comprises a first color separation nanostructure and a second color separation nanostructure provided on the first color separation nanostructure, the first color separation nanostructure and the second color separation nanostructure being provided in a multi-layer structure, and the second color separation nanostructure being closer to the central portion of the color separation nanostructure layer than the first color separation nanostructure.

13. An electronic apparatus comprising:
an image sensor configured to convert an optical image into an electrical signal; and
a processor configured to control an operation of the image sensor and store and output a signal generated by the image sensor,
wherein the image sensor comprises:
a sensor substrate comprising a plurality of photosensing cells, each of the plurality of photosensing cells being configured to sense a light;
a color separation nanostructure layer provided on the sensor substrate and comprising a plurality of color separation nanostructures, each of the plurality of color separation nanostructures being configured to separate the light according to wavelengths and concentrate each separated light on a corresponding photosensing cell among the plurality of photosensing cells;
a spacer layer provided on the color separation nanostructure layer; and
an oblique light compensation layer provided on the spacer layer and comprising a plurality of oblique light compensation nanostructures,
wherein the plurality of color separation nanostructures are arranged differently for each wavelength band that is sensed by the corresponding photosensing cell and an arrangement of the plurality of color separation nanostructures provided in a peripheral portion of the color separation nanostructure layer is same as an arrangement of the plurality of color separation nanostructures provided in a central portion of the color separation nanostructure layer, and
wherein the plurality of oblique light compensation nanostructures are configured such that a direction of oblique light incident on the oblique light compensation layer is deflected toward the color separation nanostructure layer corresponding thereto, the plurality of oblique light compensation nanostructures are arranged differently for each position of the oblique light compensation layer, and a thickness of the spacer layer is about 1 time to about 3 times a longest wavelength among the wavelengths of the light sensed by the plurality of photosensing cells.

14. The electronic apparatus of claim 13, wherein in a central portion of the oblique light compensation layer, the plurality of oblique light compensation nanostructures have a same width, and
wherein in a peripheral portion of the oblique light compensation layer, in an area corresponding to each photosensing cell, a width of an oblique light compensation nanostructure closer to the central portion of the oblique light compensation layer is greater than a width of an oblique light compensation nanostructure distant from the central portion of the oblique light compensation layer.

15. The electronic apparatus of claim 13, wherein, as a distance between an oblique light compensation nanostructure and a central portion of the oblique light compensation layer increases, a difference between a width of an oblique light compensation nanostructure closer to the central portion of the oblique light compensation layer and a width of an oblique light compensation nanostructure distant from the central portion of the oblique light compensation layer, in an area corresponding to each photosensing cell, increases.

16. The electronic apparatus of claim 13, wherein the plurality of oblique light compensation nanostructures are symmetrically arranged with respect to a direction in which the light is incident on the oblique light compensation layer, in an area corresponding to each photosensing cell.

17. The electronic apparatus of claim 13, wherein the image sensor further comprises a color filter layer arranged between the sensor substrate and the color separation nanostructure layer and comprising a plurality of filters, each of which is configured to transmit only a light in a particular wavelength band and absorb or reflect light in other wavelength bands.

18. The electronic apparatus of claim 13, wherein the image sensor further comprises another spacer layer provided between the sensor substrate and the color separation nanostructure layer, and a thickness of the another spacer layer provided between the sensor substrate and the color separation nanostructure layer is about 1.5 times to about 5 times a longest wavelength among wavelengths of a light incident on the color separation nanostructure layer.
